(19) United States
(12) Patent Application Publication
(10) Pub. No.: US 2010/0044690 A1
(43) Pub. Date: Feb. 25, 2010

(54) ORGANIC EL DISPLAY DEVICE

(76) Inventors: Satoshi OKUTANI, Ishikawa-gun (JP); Kouichi Yamashita, Kanazawa-shi (JP); Norihisa Maeda, Ishikawa-gun (JP); Hirofumi Kubota, Kanazawa-shi (JP); Masuyuki Oota, Hakusan-shi (JP); Takeshi Ikeda, Hakusan-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/535,973

(22) Filed: Aug. 5, 2009

(30) Foreign Application Priority Data
Aug. 22, 2008 (JP) 2008-214348
Jan. 7, 2009 (JP) 2009-001909
Jan. 29, 2009 (JP) 2009-017759

(51) Int. Cl. H01L 51/52

(52) U.S. Cl. 257/40; 257/89; 257/E51.022

(57) ABSTRACT

An organic EL display device includes a first organic EL element which includes a first organic layer including a first light emission layer which emits the color of light in the first wavelength range and a hole blocking layer between a pixel electrode and a counter-electrode, a second organic EL element which includes a second organic layer including a second light emission layer which emits the color of light in the first wavelength range between a pixel electrode and the counter-electrode, the second organic EL element being thinner than the first organic EL element, and a third organic EL element which includes a third organic layer including the third light emission layer which emits the color of light in the first wavelength range between a pixel electrode and the counter-electrode, the third organic EL element being thicker than the first organic EL element.

### CROSS-REFERENCE TO RELATED APPLICATIONS

This application is based upon and claims the benefit of priority from prior Japanese Patent Applications No. 2008-214348, filed Aug. 22, 2008; No. 2009-001909, filed Jan. 7, 2009; and No. 2009-017759, filed Jan. 29, 2009, the entire contents of all of which are incorporated herein by reference.

### BACKGROUND OF THE INVENTION

1. Field of the Invention

The present invention relates to an organic electroluminescence (EL) display device.

2. Description of the Related Art

In recent years, display devices using organic EL elements have vigorously been developed, which have features of self-emission, a high response speed, a wide viewing angle and a high contrast, and which can realize small thickness and light weight.

In the organic EL element, holes are injected from a hole injection electrode (anode), electrons are injected from an electron injection electrode (cathode), and the holes and electrons are recombined in a light emission layer, thereby producing light. In order to obtain full-color display, it is necessary to form pixels which emit red (R) light, green (G) light and blue (B) light, respectively. It is necessary to selectively apply light-emitting materials, which emit lights with different light emission spectra, such as red, green and blue, to light-emitting layers of organic EL elements which constitute the red, green and blue pixels. As a method for selectively applying such light-emitting materials, there is known a vacuum evaporation method. In the case of forming films of low-molecular-weight organic EL materials by such a vacuum evaporation method, there is a method in which mask evaporation is performed independently for respective color pixels by using a metallic fine mask having openings in association with the respective color pixels (see, e.g. Jpn. Pat. Appln. KOKAI Publication No. 2003-157973).

As regards the organic EL elements, there has been a demand for an increase in color purity of the organic EL element which emits blue light. Specifically, when full-color display is to be realized, if the color purity of blue is relatively low due to the characteristics of the material while the color purity of red and green is relatively high, the blue hue becomes deficient in displaying a desired color. For example, when white is to be displayed, if the blue hue is deficient, a yellow hue is produced. Thus, in order to realize a desired white balance, it is necessary to supply a large current to the organic EL element that emits blue light and to increase the luminance, thereby to compensate the deficiency of the blue hue.

This, however, leads to not only an increase in driving voltage that is needed to drive the organic EL elements, but also to a decrease in lifetime of, in particular, the organic element that emits blue light.

### BRIEF SUMMARY OF THE INVENTION

According to an aspect of the present invention, there is provided an organic EL display device comprising: a first organic EL element which includes a first anode, a cathode, and a first organic layer including a first light emission layer which emits the color of light in the first wavelength range and a hole blocking layer between the first anode and the cathode; a second organic EL element which includes a second anode, the cathode extending from the first organic EL element, and a second organic layer including a second light emission layer which emits the color of light in the first wavelength range between the second anode and the cathode, the second organic EL element being thinner than the first organic EL element; and a third organic EL element which includes a third anode, the cathode extending from the second organic EL element, and a third organic layer including a third light emission layer which emits the color of light in the first wavelength range between the third anode and the cathode, the third organic EL element being thicker than the first organic EL element.

According to another aspect of the present invention, there is provided an organic EL display device comprising an organic EL element including: an anode including a reflective layer; a first hole transport layer which is disposed above the anode; a second hole transport layer which is disposed above the first hole transport layer; a third hole transport layer which is disposed between the first hole transport layer and the second hole transport layer and includes a light-emitting material which emits red light or green light; a light emission layer which is disposed above the second hole transport layer and includes a light-emitting material which emits blue light; an electron transport layer which is disposed above the light emission layer; and a cathode including a semi-transmissive layer which is disposed above the electron transport layer.

According to still another aspect of the present invention, there is provided an organic EL display device comprising an organic EL element including: an anode including a reflective layer; a first hole transport layer which is disposed above the anode; a second hole transport layer which is disposed above the first hole transport layer; a third hole transport layer including a light-emitting material which emits red light and a fourth hole transport layer including a light-emitting material which emits green light, the third hole transport layer and the fourth hole transport layer being disposed between the first hole transport layer and the second hole transport layer; a light emission layer which is disposed on the second hole transport layer and includes a light-emitting material which emits blue light; an electron transport layer which is disposed above the light emission layer; and a cathode including a semi-transmissive layer which is disposed above the electron transport layer.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a plan view which schematically shows the structure of an organic EL display device according to an embodiment of the present invention;

FIG. 2 is a cross-sectional view which schematically shows an example of the structure that is adoptable in the organic EL display device shown in FIG. 1;

FIG. 3 is a plan view which schematically shows an example of arrangement of pixels, which is adoptable in the organic EL display device shown in FIG. 2;

FIG. 4 schematically shows an example of the structure that is adoptable in first to third organic EL elements which are included in the organic EL display device shown in FIG. 2;

FIG. 5 is a plan view of the main structure of the first to third organic EL elements shown in FIG. 4;

FIG. 6 is a cross-sectional view of a display panel including the first to third organic EL elements shown in FIG. 4;

FIG. 7 schematically shows another example of the structure that is adoptable in the first to third organic EL elements which are included in the organic EL display device shown in FIG. 2;

FIG. 8 is a plan view of the main structure of the first to third organic EL elements shown in FIG. 7;

FIG. 9 is a cross-sectional view of a display panel including the first to third organic EL elements shown in FIG. 7;

FIG. 10 schematically shows still another example of the structure that is adoptable in the first to third organic EL elements which are included in the organic EL display device shown in FIG. 2;

FIG. 11 is a plan view of the main structure of the first to third organic EL elements shown in FIG. 10;

FIG. 12 is a cross-sectional view of a display panel including the first to third organic EL elements shown in FIG. 10;

FIG. 13 schematically shows still another example of the structure that is adoptable in the first to third organic EL elements which are included in the organic EL display device shown in FIG. 2;

FIG. 14 is a cross-sectional view of a display panel including the first to third organic EL elements shown in FIG. 13;

FIG. 15 schematically shows still another example of the structure that is adoptable in the first to third organic EL elements which are included in the organic EL display device shown in FIG. 2;

FIG. 16 is a plan view of the main structure of the first to third organic EL elements shown in FIG. 15;

FIG. 17 is a cross-sectional view of a display panel including the first to third organic EL elements shown in FIG. 15;

FIG. 18 schematically shows still another example of the structure that is adoptable in the first to third organic EL elements which are included in the organic EL display device shown in FIG. 2;

FIG. 19 is a plan view of the main structure of the first to third organic EL elements shown in FIG. 18;

FIG. 20 is a cross-sectional view of a display panel including the first to third organic EL elements shown in FIG. 18;

FIG. 21 schematically shows still another example of the structure that is adoptable in the first to third organic EL elements which are included in the organic EL display device shown in FIG. 2;

FIG. 22 is a plan view of the main structure of the first to third organic EL elements shown in FIG. 21;

FIG. 23 is a cross-sectional view of a display panel including the first to third organic EL elements shown in FIG. 21;

FIG. 24 is a graph showing an example of the relationship between an emission spectrum and an absorption spectrum of emission light;

FIG. 25 schematically shows still another example of the structure that is adoptable in the first to third organic EL elements which are included in the organic EL display device shown in FIG. 2;

FIG. 26 is a plan view of the main structure of the first to third organic EL elements shown in FIG. 25;

FIG. 27 is a cross-sectional view of a display panel including the first to third organic EL elements shown in FIG. 25;

FIG. 28 schematically shows still another example of the structure that is adoptable in the first to third organic EL elements which are included in the organic EL display device shown in FIG. 2;

FIG. 29 is a plan view of the main structure of the first to third organic EL elements shown in FIG. 28;

FIG. 30 is a cross-sectional view of a display panel including the first to third organic EL elements shown in FIG. 28;

FIG. 31 schematically shows still another example of the structure that is adoptable in the first to third organic EL elements which are included in the organic EL display device shown in FIG. 2;

FIG. 32 is a plan view of the main structure of the first to third organic EL elements shown in FIG. 31; and

FIG. 33 is a cross-sectional view of a display panel including the first to third organic EL elements shown in FIG. 31.

### DETAILED DESCRIPTION OF THE INVENTION

An embodiment of the present invention will now be described in detail with reference to the accompanying drawings. In the drawings, structural elements having the same or similar functions are denoted by like reference numerals, and an overlapping description is omitted.

In the present embodiment, as an example of the organic EL display device, a description is given of an organic EL display device of a top emission type, which adopts an active matrix driving method.

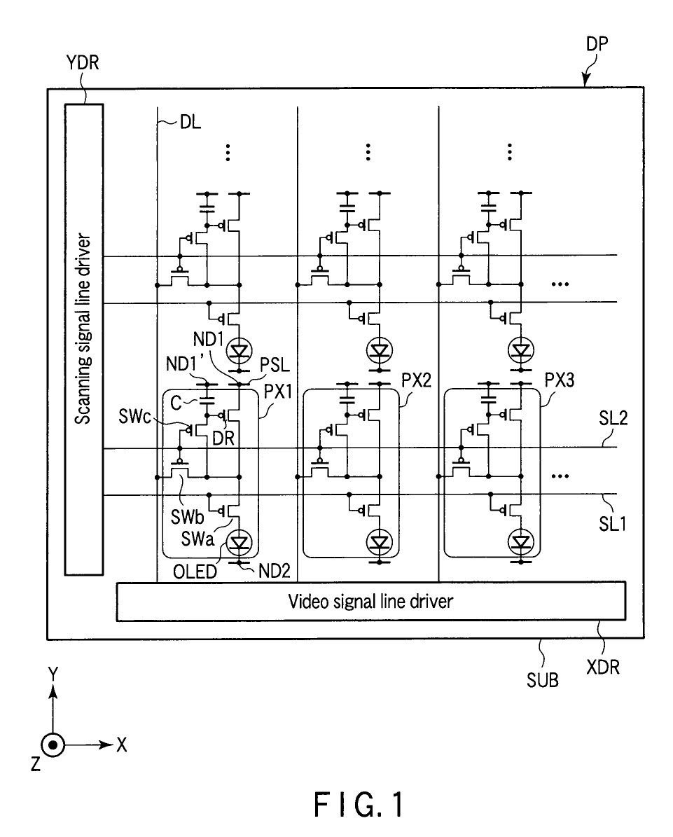

As shown in FIG. 1, this organic EL display device includes a display panel DP. The display panel DP includes an insulative substrate SUB such as a glass substrate.

Pixels PX1 to PX3 are arranged in an X direction in the named order, and constitute a triplet (unit pixel) which is a minimum unit of a display pixel. In a display region, such triplets are arranged in the X direction and Y direction. Specifically, in the display region, a pixel string in which pixels PX1 are arranged in the Y direction, a pixel string in which pixels PX2 are arranged in the Y direction and a pixel string in which pixels PX3 are arranged in the Y direction are arranged in the X direction in the named order, and these three pixel strings are repeatedly arranged in the X direction.

Scanning signal lines SL1 and SL2 extend in the X direction, and are alternately arranged in the Y direction. Video signal lines DL extend in the Y direction, and are arranged in the X direction.

Each of the pixels PX1 to PX3 includes a driving transistor DR, switching transistors SWa to SWc, an organic EL element OLED, and a capacitor C. In this example, the driving transistor DR and switching transistors SWa to SWc are p-channel thin-film transistors.

The driving transistor DR, switching transistor SWa and organic EL element OLED are connected in series in the named order between a first power supply terminal ND1 and a second power supply terminal ND2. In this example, the power supply terminal ND1 is a high-potential power supply terminal, and the power supply terminal ND2 is a low-potential power supply terminal. The power supply terminal ND1 is connected to a power supply line PSL.

The gate of the switching transistor SWa is connected to the scanning signal line SL1. The switching transistor SWb is connected between the video signal line DL and the drain of the driving transistor DR, and the gate of the switching transistor SWb is connected to the scanning signal line SL2. The switching transistor SWc is connected between the drain and gate of the driving transistor DR, and the gate of the switching transistor SWc is connected to the scanning signal line SL2. The capacitor C is connected between the gate of the driving transistor DR and a constant potential terminal ND1′. In this example, the constant potential terminal ND1′ is connected to the power supply terminal ND1.

A video signal line driver XDR and a scanning signal line driver YDR are disposed, for example, on the substrate SUB. Specifically, the video signal line driver XDR and scanning signal line driver YDR are implemented by chip on glass (COG). The video signal line driver XDR and scanning signal line driver YDR may be implemented by tape carrier package (TCP), instead of COG. Alternatively, the video signal line driver XDR and scanning signal line driver YDR may be directly formed on the substrate SUB.

The video signal lines DL are connected to the video signal line driver XDR. The video signal line driver XDR outputs current signals as video signals to the video signal lines DL.

The scanning signal lines SL1 and SL2 are connected to the scanning signal line driver YDR. The scanning signal line driver YDR outputs voltage signals as first and second scanning signals to the scanning signal lines SL1 and SL2.

When an image is to be displayed on this organic EL display device, for example, the scanning signal lines SL2 are successively scanned. Specifically, the pixels PX1 to PX3 are selected on a row-by-row basis. In a selection period in which a certain row is selected, a write operation is executed in the pixels PX1 to PX3 included in this row. In a non-selection period in which this row is not selected, a display operation is executed in the pixels PX1 to PX3 included in this row.

In the selection period in which the pixels PX1 to PX3 of a certain row are selected, the scanning signal line driver YDR outputs, as voltage signals, scanning signals for opening (rendering non-conductive) the switching transistors SWa to the scanning signal line SL1 to which the pixels PX1 to PX3 are connected. Then, the scanning signal line driver YDR outputs, as voltage signals, scanning signals for closing (rendering conductive) the switching transistors SWb and SWc to the scanning signal line SL2 to which the pixels PX1 to PX3 are connected. In this state, the video signal line driver XDR outputs, as current signals (write current) I_{sig}, video signals to the video signal lines DL, and sets a gate-source voltage V_{gs} of the driving transistor DR at a magnitude corresponding to the video signal I_{sig}.

Subsequently, the scanning signal line driver YDR outputs, as voltage signals, scanning signals for opening the switching transistors SWb and SWc to the scanning signal line SL2 to which the pixels PX1 to PX3 are connected, and then outputs, as voltage signals, scanning signals for closing the switching transistors SWa to the scanning signal line SL1 to which the pixels PX1 to PX3 are connected. Thus, the selection period ends.

In the non-selection period following the selection period, the switching transistors SWa are kept closed, and the switching transistors SWb and SWc are kept opened. In the non-selection period, a driving current I_{drv}, which corresponds in magnitude to the gate-source voltage V_{gs} of the driving transistor DR, flows in the organic EL element OLED. The organic EL element OLED emits light with a luminance corresponding to the magnitude of the driving current I_{drv} In this case, I_{drv}≅I_{sig}, and emission light corresponding to the current signal (write current) I_{sig} can be obtained in each pixel.

In the above-described example, the structure in which the current signal is written as the video signal is adopted in the pixel circuit for driving the organic EL element OLED. Alternatively, a structure in which a voltage signal is written as the video signal may be adopted in the pixel circuit. The invention is not restricted to the above-described example. In the present embodiment, use is made of p-channel thin-film transistors. Alternatively, n-channel thin-film transistors may be used, with the spirit of the invention being unchanged. The pixel circuit is not limited to the above-described example, and various modes may be applicable to the pixel circuit.

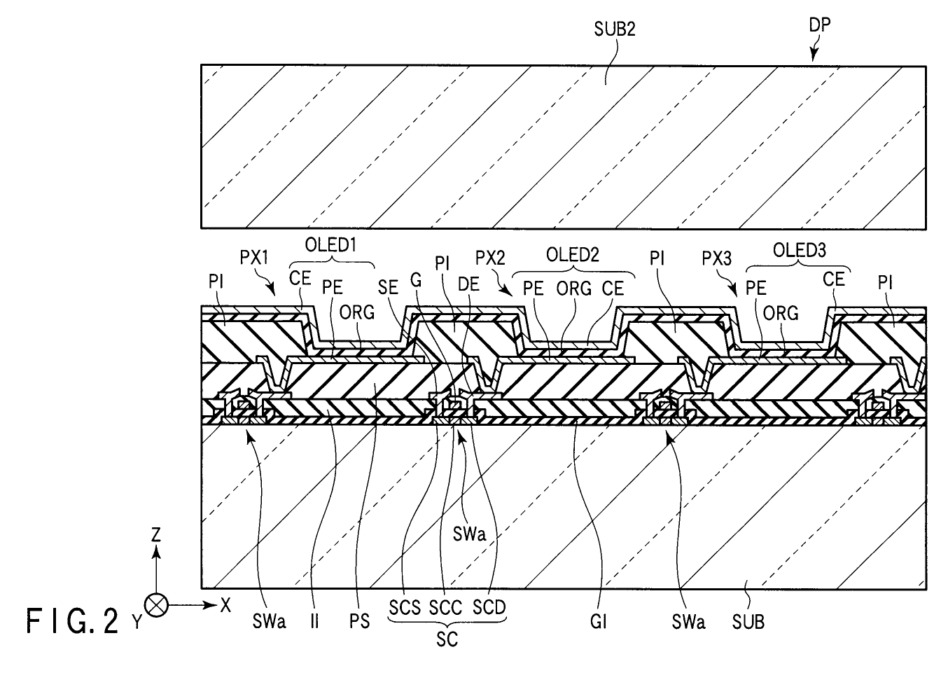

FIG. 2 schematically shows the cross-sectional structure of the display panel DP which includes the switching transistors SWa and the organic EL elements OLED.

As shown in FIG. 2, a semiconductor layer SC of the switching transistor SWa is disposed on the substrate SUB. The semiconductor layer SC is formed of, e.g. polysilicon. In the semiconductor layer SC, a source region SCS and a drain region SCD are formed, with a channel region SCC being interposed.

The semiconductor layer SC is coated with a gate insulation film GI. The gate insulation film GI is formed by using, e.g. tetraethyl orthosilicate (TEOS). The gate G of the switching transistor SWa is disposed on the gate insulation film GI immediately above the channel region SCC. The gate G is a part of the scanning signal line SL1, and may be formed of the same material in the same fabrication step as the above-described scanning signal line SL2. The gate G is formed of, e.g. molybdenum-tungsten (MoW).

In this example, the switching transistor SWa is a top-gate-type p-channel thin-film transistor, and has the same structure as the above-described driving transistor DR and other switching transistors SWb and SWc.

The gate insulation film GI and the gate G, together with the scanning signal lines SL1 and SL2, are coated with an interlayer insulation film II. The interlayer insulation film II is formed by using, e.g. silicon oxide (SiOₓ) which is deposited by, e.g. plasma chemical vapor deposition (CVD).

A source SE and a drain DE of the switching transistor SWa are disposed on the interlayer insulation film II. The source SE is connected to the source region SCS of the semiconductor layer SC via a contact hole which is formed in the interlayer insulation film II and gate insulation film GI. The drain DE is connected to the drain region SCD of the semiconductor layer SC via a contact hole which is formed in the interlayer insulation film II and gate insulation film GI.

The source SE and drain DE have, for example, a three-layer structure of molybdenum (Mo)/aluminum (Al)/molybdenum (Mo), and can be formed by the same process. The source SE and drain DE are coated with a passivation film PS. The passivation film PS is formed by using, e.g. silicon nitride (SiNₓ).

Pixel electrodes PE are disposed on the passivation film PS in association with the pixels PX1 to PX3. Each pixel electrode PE is connected to the drain DE of the switching transistor SWa via a contact hole which is formed in the passivation film PS. In this example, the pixel electrode PE corresponds to an anode.

A partition wall PI is formed on the passivation film PS. The partition wall PI is disposed in a lattice shape in a manner to surround the entire periphery of the pixel electrode PE. The partition wall PI may be disposed in a stripe shape extending in the Y direction between the pixel electrodes PE. The partition wall PI is, for instance, an organic insulation layer. The partition wall PI can be formed by using, for example, a photolithography technique.

An organic layer ORG is disposed on each pixel electrode PE. The organic layer ORG includes at least one continuous film which extends over the display region including all pixels PX1 to PX3. Specifically, the organic layer ORG covers the pixel electrodes PE and partition wall PI. The details will be described later.

The organic layer ORG is coated with a counter-electrode CE. In this example, the counter-electrode CE corresponds to a cathode. The counter-electrode CE is a continuous film which extends over the display region including all pixels PX1 to PX3. In short, the counter-electrode CE is a common electrode which is shared by the pixels PX1 to PX3.

The pixel electrodes PE, organic layers ORG and counter-electrode CE constitute organic EL elements which are disposed in association with the respective pixels.

Specifically, the pixel PX1 includes a first organic EL element OLED1, the pixel PX2 includes a second organic EL element OLED2, and the pixel PX3 includes a third organic EL element OLED3. Although FIG. 2 shows one first organic EL element OLED1 of the pixel PX1, one second organic EL element OLED2 of the pixel PX2 and one third organic EL element OLED3 of the pixel PX3, these organic EL elements OLED1, OLED2 and OLED3 are repeatedly disposed in the X direction. Specifically, another first organic EL element OLED1 is disposed adjacent to the third organic EL element OLED3 that is shown on the right side part of FIG. 2. Similarly, another third organic EL element OLED3 is disposed adjacent to the first organic EL element OLED1 that is shown on the left side part of FIG. 2.

The partition wall PI is disposed between, and divides, the first organic EL element OLED1 and second organic EL element OLED2. In addition, the partition wall PI is disposed between, and divides, the second organic EL element OLED2 and third organic EL element OLED3. Further, the partition wall PI is disposed between, and divides, the third organic EL element OLED3 and first organic EL element OLED1.

The sealing of the first to third organic EL elements OLED1 to OLED3 may be effected by bonding a sealing glass substrate SUB2, to which a desiccant is attached, by means of a sealant which is applied to the periphery of the display region. Alternatively, the sealing of the first to third organic EL elements OLED1 to OLED3 may be effected by bonding the sealing glass substrate SUB2 by means of frit glass (frit sealing), or by filling an organic resin layer between the sealing glass substrate SUB2 and the organic EL element OLED (solid sealing). In the case of the frit sealing, the desiccant may be dispensed with. In the case of the solid sealing, an insulation film of an inorganic material, in addition to the organic resin layer, may be interposed between the sealing glass substrate SUB2 and the counter-electrode CE.

In the present embodiment, the first to third organic EL elements OLED1 to OLED3 are configured to have different emission light colors. In this example, the emission light color of the first organic EL element OLED1 is red, the emission light color of the second organic EL element OLED2 is green, and the emission light color of the third organic EL element OLED3 is blue.

In general, the color of light in the range of wavelengths of 400 nm to 435 nm is defined as purple; the color of light in the range of wavelengths of 435 nm to 480 nm is defined as blue; the color of light in the range of wavelengths of 480 nm to 490 nm is defined as greenish blue; the color of light in the range of wavelengths of 490 nm to 500 nm is defined as bluish green; the color of light in the range of wavelengths of 500 nm to 560 nm is defined as green; the color of light in the range of wavelengths of 560 nm to 580 nm is defined as yellowish green; the color of light in the range of wavelengths of 580 nm to 595 nm is defined as yellow; the color of light in the range of wavelengths of 595 nm to 610 nm is defined as orange; the color of light in the range of wavelengths of 610 nm to 750 nm is defined as red; and the color of light in the range of wavelengths of 750 nm to 800 nm is defined as purplish red. In this example, the color of light with a major wavelength in the range of wavelengths of 400 nm to 490 nm is defined as blue (a third wavelength range); the color of light with a major wavelength, which is greater than 490 nm and less than 595 nm, is defined as green (a second wavelength range); and the color of light with a major wavelength in the range of wavelengths of 595 nm to 800 nm is defined as red (a first wavelength range).

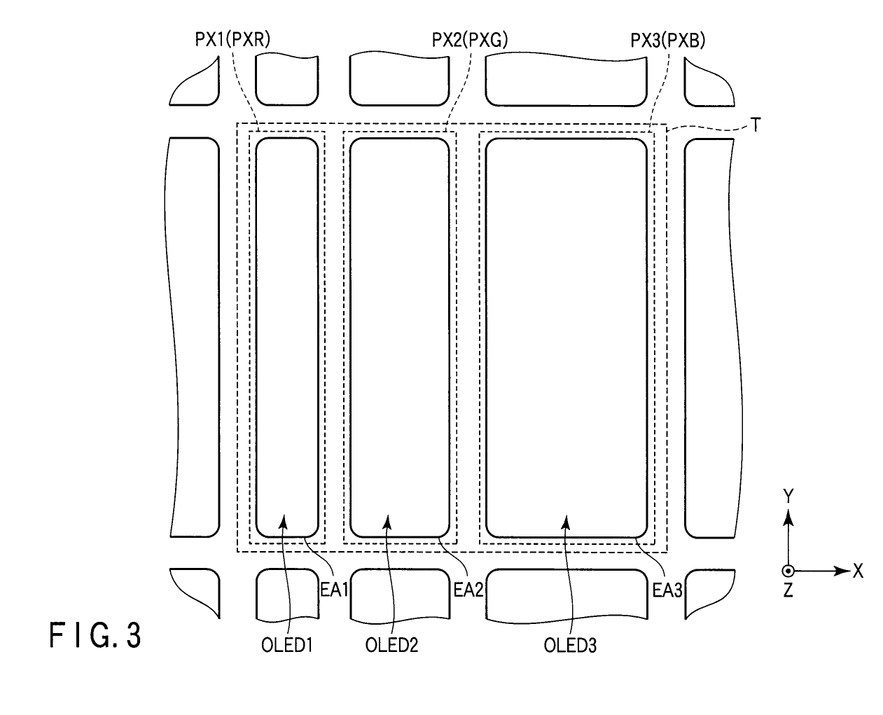

FIG. 3 shows a structure example of a triplet T. The triplet T is formed in a square shape with substantially equal lengths in the X direction and Y direction. The triplet T is composed of a pixel PX1, a pixel PX2 and a pixel PX3. The pixel PX1 includes a first organic EL element OLED1, and functions as a red pixel PXR which displays red. The pixel PX2 includes a second organic EL element OLED2, and functions as a green pixel PXG which displays green. The pixel PX3 includes a third organic EL element OLED3, and functions as a blue pixel PXB which displays blue.

Each of a light emission section EA1 of the first organic EL element OLED1, a light emission section EA2 of the second organic EL element OLED2 and a light emission section EA3 of the third organic EL element OLED3 is formed in a rectangular shape extending in the Y direction.

The relationship in area between the light emission sections EA1 to EA3 is as follows:

the area of first light emission section EA1<the area of second light emission section EA2<the area of third light emission section EA3.

An example of the ratio in area between the light emission sections EA1 to EA3 is as follows:

EA1:EA2:EA3=1:1.3:2.7.

In this example, since the lengths of the light emission sections EA1 to EA3 in the Y direction are substantially equal, the above-described ratio in area is set according to the lengths of the light emission sections EA1 to EA3 in the X direction.

In this manner, the light emission section EA3, which emits blue light, is so formed as to have a larger area than each of the light emission section EA1 and light emission section EA1 which emit lights of the other colors. Accordingly, since the amount of carriers, which are supplied to the light emission section EA3, increases, it is possible to avoid an increase in driving voltage that is necessary for providing an adequate blue hue component. Therefore, the lifetime of the third organic EL element OLED3, which displays blue, can be increased.

The areas of the light emission sections EA1 to EA3 may be varied so as to obtain desired characteristics. The relationship in area between the light emission sections EA1 to EA3 is not limited to the example shown in FIG. 3, and may be made substantially equal to each other.

### EXAMPLE 1

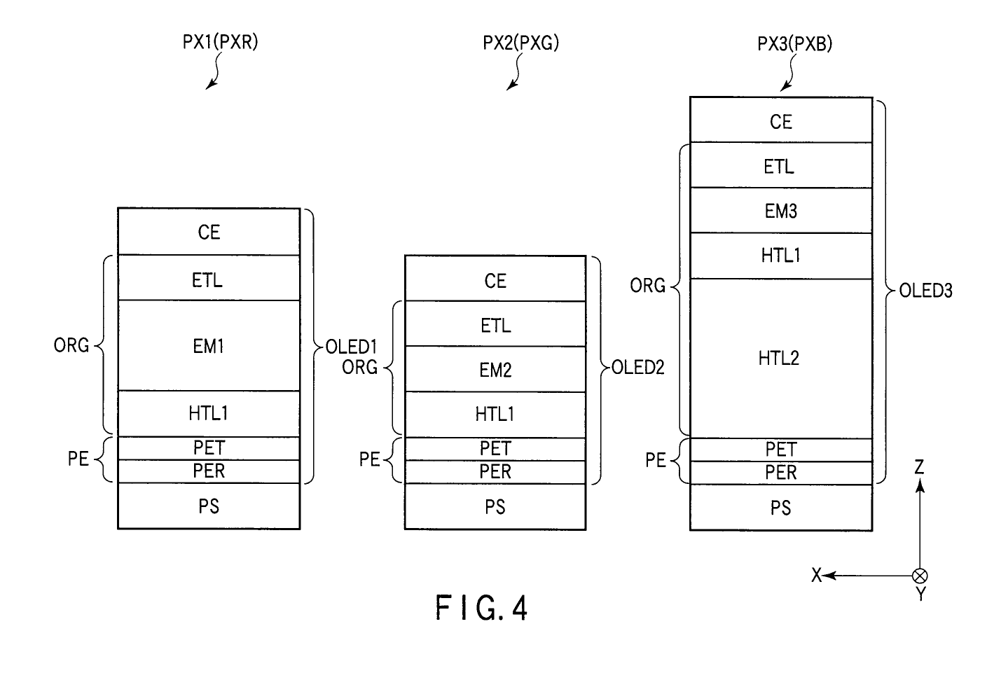

FIG. 4 schematically shows the structures of the first to third organic EL elements OLED1 to OLED3 in Example 1. As shown in FIG. 4, the first organic EL element OLED1 of the pixel PX1, the second organic EL element OLED2 of the pixel PX2 and the third organic EL element OLED3 of the pixel PX3 are disposed on the passivation film PS. Each of the first to third organic EL elements OLED1 to OLED3 includes a pixel electrode PE, a counter-electrode CE which is opposed to the pixel electrode PE, and an organic layer ORG which is interposed between the pixel electrode PE and the counter-electrode CE.

The first organic EL element OLED1 is constructed as follows. Specifically, the pixel electrode PE of the first organic EL element OLED1 includes a reflective layer PER which is disposed on the passivation film PS, and a transmissive layer PET which is disposed on the reflective layer. The organic layer (first organic layer) ORG of the first organic EL element OLED1 is disposed on the pixel electrode PE. This organic layer ORG includes a first hole transport layer HTL1 which is disposed on the transmissive layer PET, a first light emission layer EM1 which is disposed on the first hole transport layer HTL1, and an electron transport layer ETL which is disposed on the first light emission layer EM1. The counter-electrode CE of the first organic EL element OLED1 is disposed on the electron transport layer ETL of the organic layer ORG.

The second organic EL element OLED2 is constructed as follows. Specifically, the pixel electrode PE of the second organic EL element OLED2 includes a reflective layer PER which is disposed on the passivation film PS, and a transmissive layer PET which is disposed on the reflective layer. The organic layer (second organic layer) ORG of the second organic EL element OLED2 is disposed on the pixel electrode PE. This organic layer ORG includes a first hole transport layer HTL1 which is disposed on the transmissive layer PET, a second light emission layer EM2 which is disposed on the first hole transport layer HTL1, and an electron transport layer ETL which is disposed on the second light emission layer EM2. The counter-electrode CE of the second organic EL element OLED2 is disposed on the electron transport layer ETL of the organic layer ORG.

The third organic EL element OLED3 is constructed as follows. Specifically, the pixel electrode PE of the third organic EL element OLED3 includes a reflective layer PER which is disposed on the passivation film PS, and a transmissive layer PET which is disposed on the reflective layer. The organic layer (third organic layer) ORG of the third organic EL element OLED3 is disposed on the pixel electrode PE. This organic layer ORG includes a second hole transport layer HTL2 which is disposed on the transmissive layer PET, a first hole transport layer HTL1 which is disposed on the second hole transport layer HTL2, a third light emission layer EM3 which is disposed on the first hole transport layer HTL1, and an electron transport layer ETL which is disposed on the third light emission layer EM3. The counter-electrode CE of the third organic EL element OLED3 is disposed on the electron transport layer ETL of the organic layer ORG.

The pixel electrodes PE of the first to third organic EL elements OLED1 to OLED3 have the same structure, that is, the two-layer structure in which the transmissive layer PET is stacked on the reflective layer PER. The reflective layer PER, which is disposed between the passivation film PS and the transmissive layer PET, is formed of, e.g. silver (Ag). Alternatively, the reflective layer PER may be formed of other electrically conductive material with light reflectivity, such as aluminum (Al). The transmissive layer PET, which is disposed between the reflective layer PER and the organic layer ORG, is formed of, e.g. indium tin oxide (ITO). Alternatively, the transmissive layer PET may be formed of other electrically conductive material with light transmissivity, such as indium zinc oxide (IZO). The pixel electrodes PE of the first to third organic EL elements OLED1 to OLED3 have substantially equal thickness.

The first hole transport layer HTL1 is formed of, e.g. N,N′-diphenyl-N,N′-bis(1-naphtylphenyl)-1,1′-biphenyl-4,4′-diamine(α-NPD). Alternatively, the first hole transport layer HTL1 may be formed of other material. The first hole transport layers HTL1 of the first to third organic EL elements OLED1 to OLED3 have substantially equal thickness.

The second hole transport layer HTL2 of the third organic EL element OLED3 may be formed of the same material as the first hole transport layer HTL1, but it may be formed of other material.

The electron transport layer ETL is formed of, e.g. Alq₃, but it may be formed of other material. The electron transport layers ETL of the first to third organic EL elements OLED1 to OLED3 have substantially equal thickness.

Each of the first to third light emission layers EM1 to EM3 includes a host material. As the host material, for instance, 4,4′-bis(2,2′-diphenyl-ethen-1-yl)-diphenyl (BPVBI) is usable, but other material may be used.

The first light emission layer EM1 includes a first light-emitting material (dopant material) which is formed of a luminescent organic compound or composition having a central light emission wavelength in red wavelengths. As the first light-emitting material, for instance, 4-(Dicyanomethylene)-2-methyl-6-(julolidin-4-yl-vinyl)-4H-pyran (DCM2) is usable, but other material may be used.

The second light emission layer EM2 includes a second light-emitting material (dopant material) which is formed of a luminescent organic compound or composition having a central light emission wavelength in green wavelengths. As the second light-emitting material, for instance, tris(8-hydroxyquinolato)aluminum (Alq₃) is usable, but other material may be used.

The third light emission layer EM3 includes a third light-emitting material (dopant material) which is formed of a luminescent organic compound or composition having a central light emission wavelength in blue wavelengths. As the third light-emitting material, for instance, bis[(4,6-difluorophenyl)-pyridinato-N,C2′](picorinate)iridium(III) (FIrpic) is usable, but other material may be used.

The first light-emitting material, second light-emitting material and third light-emitting material may be fluorescent materials or phosphorescent materials.

The counter-electrode CE has a single-layer structure which is composed of a semi-transmissive layer. The counter-electrode CE is formed of, e.g. magnesium-silver, but it may be formed of other electrically conductive material. The counter-electrodes CE of the first to third organic EL elements OLED1 to OLED3 have substantially equal thickness.

In the present embodiment, each of the first to third organic EL elements OLED1 to OLED3 adopts a top-emission-type structure in which emission light is extracted from the counter-electrode side. In addition, each of the first to third organic EL elements OLED1 to OLED3 adopts a micro-cavity structure which is composed of the reflective layer PER of the pixel electrode PE, and the counter-electrode CE that is formed of a semi-transmissive layer. In the meantime, in the case where either of the cathode and anode, which sandwich the organic layer ORG, is composed of only a transparent electrode, the micro-cavity structure cannot be obtained.

In the present embodiment, the thickness of the second organic EL element OLED2 is less than that of the first organic EL element OLED1. The thickness of the third organic EL element OLED3 is greater than that of the first organic EL element OLED1. The thickness (or film thickness), in this context, corresponds to the distance in a normal direction of the passivation film PS, that is, in the Z direction. The thickness of each of the first to third organic EL elements OLED1 to OLED3 corresponds to the distance between the pixel electrode PE and the counter-electrode CE along the Z direction of the passivation film PS.

The relationship in thickness among the first to third organic EL elements OLED1 to OLED3 is as follows:

the second organic EL element OLED2<the first organic EL element OLED1<the third organic EL element OLED3.

The relationship between the first to third organic EL elements OLED1 to OLED3, with respect to the thickness between the reflective layer PER and the counter-electrode CE that is the semi-transmissive layer, is as follows:

the thickness in the second organic EL element<the thickness in the first organic EL element<the thickness in the third organic EL element.

In the above-described structure, the first organic EL element OLED 1 and the second organic EL element OLED2 may adopt device structures which make use of the interference effect of the same order. For example, the first organic EL element OLED 1 and the second organic EL element OLED2 may adopt device structures which make use of the interference effect of a 0th order.

The third organic EL element OLED3 may adopt a device structure which makes use of the interference effect of a higher order than the first organic EL element OLED 1 and the second organic EL element OLED2. For example, the third organic EL element OLED3 may adopt a device structure which makes use of the interference effect of a first order.

The difference in thickness between the first to third organic EL elements OLED1 to OLED3 is created by the film thicknesses of the first light emission layer EM1, second light emission layer EM2, third light emission layer EM3 and second hole transport layer HTL2.

In the example shown in FIG. 4, the first light emission layer EM1 has a greater film thickness than the second light emission layer EM2, and the first organic EL element OLED1 is formed to be thicker than the second organic EL element OLED2. In addition, the second hole transport layer HTL2 and the third light emission layer EM3 have such film thicknesses that the third organic EL element OLED3 is formed to be thicker than the first organic EL element OLED1.

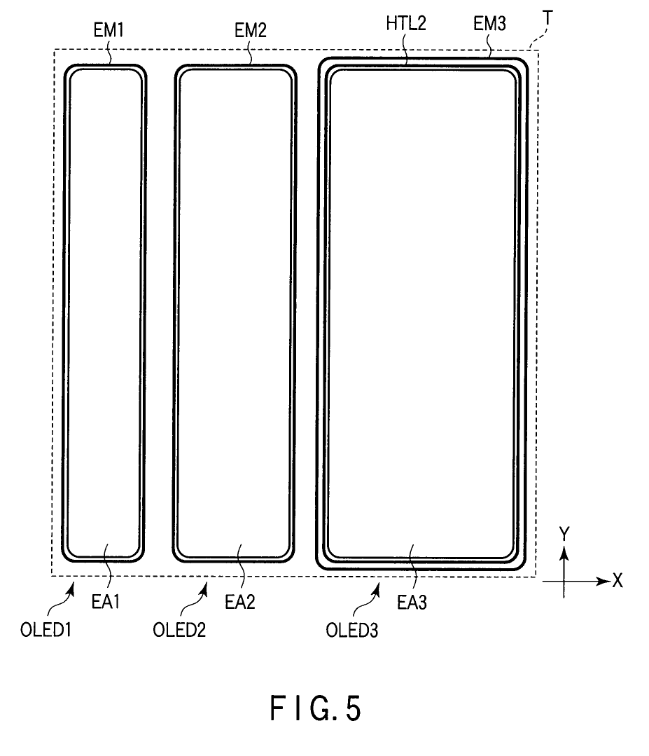

FIG. 5 schematically shows the first light emission layer EM1, second light emission layer EM2, third light emission layer EM3 and second hole transport layer HTL2, which are disposed in the triplet T in Example 1.

As shown in FIG. 5, the first light emission layer EM1 is disposed on an area which is equal to or greater than the area of the light emission section EA1 of the first organic EL element OLED1. The second light emission layer EM2 is disposed on an area which is equal to or greater than the area of the light emission section EA2 of the second organic EL element OLED2. The third light emission layer EM3 and second hole transport layer HTL2 are disposed on an area which is equal to or greater than the area of the light emission section EA3 of the third organic EL element OLED3.

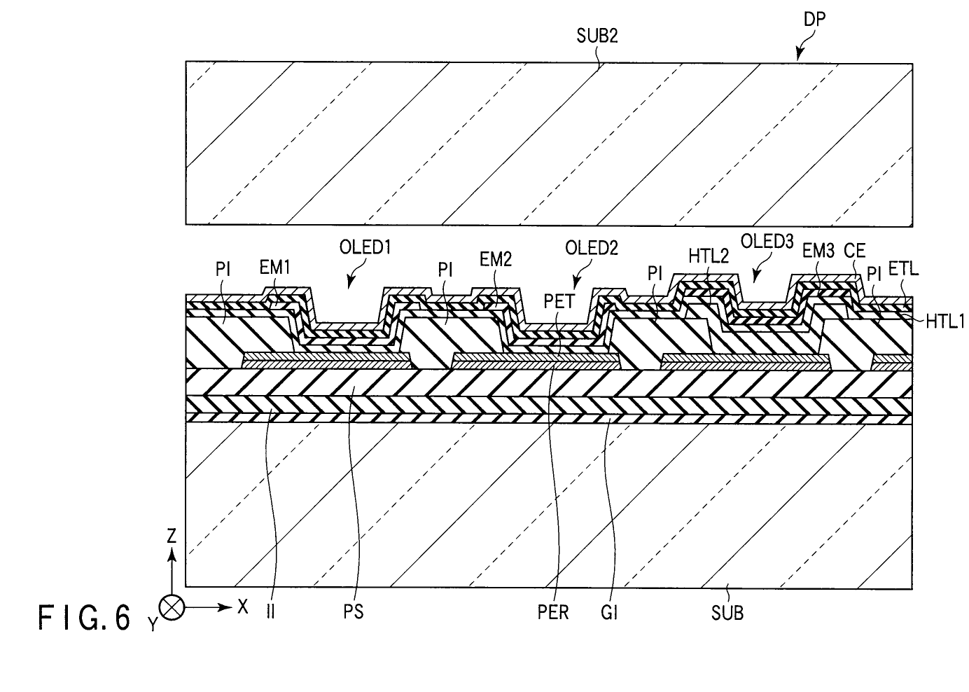

FIG. 6 schematically shows a cross-sectional structure of the display panel DP which includes the first to third organic EL elements OLED1 to OLED3 in Example 1. In FIG. 6, the dimensions in the X direction are different from those in FIG. 5 in order to clarify the structures of the first to third organic EL elements OLED1 to OLED3.

As shown in FIG. 6, the gate insulation film GI, interlayer insulation film II and passivation film PS are disposed between the substrate SUB and the reflective layer PER of each of the first to third organic EL elements OLED1 to OLED3. The transmissive layer PET of each of the first to third organic EL elements OLED1 to OLED3 is disposed on the reflective layer PER.

The second hole transport layer HTL2 is disposed on the transmissive layer PET of the third organic EL element OLED3. Part of the second hole transport layer HTL2 extends onto the partition wall PI which surrounds the third organic EL element OLED3.

The first hole transport layer HTL1 is disposed on the transmissive layers PET of the first and second organic EL elements OLED1 and OLED2 and on the second hole transport layer HTL2 of the third organic EL element OLED3. The first hole transport layer HTL1 extends over the first to third organic EL elements OLED1 to OLED3.

Specifically, the first hole transport layer HTL1 is a continuous film spreading over the display region and is disposed common to the first to third organic EL elements OLED1 to OLED3. In addition, the first hole transport layer HTL1 is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed on the first hole transport layer HTL1 of the first organic EL element OLED1. Part of the first light emission layer EM1 extends onto the partition wall PI surrounding the first organic EL element OLED1.

The second light emission layer EM2 is disposed on the first hole transport layer HTL1 of the second organic EL element OLED2. Part of the second light emission layer EM2 extends onto the partition wall PI surrounding the second organic EL element OLED2.

The third light emission layer EM3 is disposed on the first hole transport layer HTL1 of the third organic EL element OLED3. Part of the third light emission layer EM3 extends onto the partition wall PI surrounding the third organic EL element OLED3.

The electron transport layer ETL is disposed on the first light emission layer EM1 of the first organic EL element OLED1, on the second light emission layer EM2 of the second organic EL element OLED2, and on the third light emission layer EM3 of the third organic EL element OLED3. The electron transport layer ETL extends over the first to third organic EL elements OLED1 to OLED3.

Specifically, the electron transport layer ETL is a continuous film spreading over the display region and is disposed common to the first to third organic EL elements OLED1 to OLED3. In addition, the electron transport layer ETL is disposed on the first hole transport layer HTL1 above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The counter-electrode CE is disposed on the electron transport layer ETL of the first to third organic EL elements OLED1 to OLED3. The counter-electrode CE extends over the first to third organic EL elements OLED1 to OLED3.

Specifically, the counter-electrode CE is a continuous film spreading over the display region and is disposed common to the first to third organic EL elements OLED1 to OLED3. In addition, the counter-electrode CE is disposed on the electron transport layer ETL above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first to third organic EL elements OLED1 to OLED3 are sealed by using the sealing glass substrate SUB2.

Examples of the thicknesses of the first to third organic EL elements OLED1 to OLED3 are shown below. In the first organic EL element OLED1, the total film thickness between the reflective layer PER and the counter-electrode CE is 120 nm. In the second organic EL element OLED2, the total film thickness between the reflective layer PER and the counter-electrode CE is 95 nm. In the third organic EL element OLED3, the total film thickness between the reflective layer PER and the counter-electrode CE is 192 nm.

In the present embodiment, however, because of the restrictions due to the interference structure, in order to secure the color purity of emission light, the total film thickness between the reflective layer PER and the counter-electrode CE in the first organic EL element OLED1 should preferably be set in a range of 110 nm to 130 nm. Similarly, the total film thickness between the reflective layer PER and the counter-electrode CE in the second organic EL element OLED2 should preferably be set in a range of 85 nm to 105 nm, and the total film thickness between the reflective layer PER and the counter-electrode CE in the third organic EL element OLED3 should preferably be set in a range of 182 nm to 202 nm.

Thereby, in the present embodiment, the first organic EL element OLED1 and second organic EL element OLED2 adopt the 0th-order interference structure. The third organic EL element OLED3 adopts the first-order interference structure.

As has been described above, the third organic EL element OLED3, which emits blue light, is formed to be thicker than the organic EL elements which emit lights of colors having longer wavelengths than blue light, namely, the first organic EL element OLED1 which emits red light and the second organic EL element OLED2 which emits green light. Since the third organic EL element OLED3 can adopt the device structure which makes use of the interference effect of the higher order than the first organic EL element OLED1 and second organic EL element OLED2, the color purity of the blue light that is emitted can be improved.

Thus, the third organic EL element OLED3 can display a desired color even if light is emitted at a low luminance. Thereby, it is possible to avoid an increase in driving voltage that is necessary for providing an adequate blue hue component of the third organic EL element OLED3. Therefore, the lifetime of the third organic EL element OLED3 can be increased.

In the case where the device structure, which makes use of the interference effect of the same order, is adopted in the first to third organic EL elements OLED1 to OLED3, the third organic EL element OLED3 is formed to have the smallest thickness since the third organic EL element OLED3 emits light of the shortest wavelength. In this case, in the third organic EL element OLED3, since the distance between the third light emission layer EM3 and the counter-electrode CE is relatively short, excitons are attracted to the counter-electrode CE and do not contribute to light emission, leading to light extinction. Owing to the extinction, the decrease in light emission efficiency becomes conspicuous. If an adequate distance is to be secured between the third light emission layer EM3 and the counter-electrode CE, the thickness of the pixel electrode side of the third light emission layer EM3 becomes small because the thickness of the entire device is determined in order to make use of the interference effect of the same order. In this case, the thickness of the hole transport layer HTL decreases, and a carrier balance deteriorates.

According to the present embodiment, the third organic EL element OLED3 can adopt the device structure which makes use of the interference effect of the higher order than the first organic EL element OLED1 and second organic EL element OLED2. Thus, in the third organic EL element OLED3 with the above-described structure, a sufficient distance between the third light emission layer EM3 and the counter-electrode CE can be secured, as in the first organic EL element OLED1 and second organic EL element OLED2, and the occurrence of light extinction in the counter-electrode CE can be suppressed. In addition, in the third organic EL element OLED3, a sufficient thickness of the hole transport layers HTL1 and HTL2 between the third light emission layer EM3 and the pixel electrode PE can be secured, and the carrier balance can be improved. Therefore, the light emission efficiency of the third organic EL element OLED3 can be improved.

Furthermore, since the first organic EL element OLED1 and second organic EL element OLED2 can adopt the device structure which makes use of the interference effect of a lower order, the thickness of the entire device can be decreased, and an increase in driving voltage can be avoided. Therefore, the power consumption can be decreased in the entirety of the first to third organic EL elements OLED1 to OLED 3.

According to the present embodiment, it was confirmed that high color purity was successfully obtained in all the first to third organic EL elements OLED1 to OLED 3. In addition, it was confirmed that no coloring occurred at the time of displaying white, and multi-color display of desired colors was effected.

According to this embodiment, the first hole transport layer HTL1, electron transport layer ETL and counter-electrode CE are common layers, and are continuous films spreading over the display region. Thus, when these films are formed by evaporation deposition, there is no need to use a fine mask in which fine openings corresponding to the light emission sections EA1 to EA3 are formed, and the manufacturing cost of the mask can be reduced. In addition, the amount of material, which is deposited on the mask at the time of forming the first hole transport layer HTL1, electron transport layer ETL and counter-electrode CE, decreases, and the efficiency of use of the material for forming these films is enhanced.

Besides, according to the present embodiment, the top-emission-type structure is adopted. Specifically, unlike the structure in which emission light is extracted from the substrate SUB side, emission light can be extracted from the side opposite to the substrate SUB, without restrictions to the aperture ratio due to various thin-film transistors and various wirings which are disposed on the substrate SUB. Therefore, the areas of the light emission sections EA1 to EA3 of the first to third organic EL elements OLED1 to OLED3 can sufficiently be secured, and higher fineness can advantageously be achieved.

Next, a description is given of examples of device variations which can be adopted in the first to third organic EL elements OLED1 to OLED3 in the present embodiment.

For example, in each organic layer ORG, a thin film with a hole injection function, namely, a hole injection layer, may be provided between the pixel electrode PE and the first hole transport layer HTL1. The hole injection layer can be formed of, e.g. copper phthalocyanine.

It should suffice if the counter-electrode CE includes at least a semi-transmissive layer. The structure of the counter-electrode CE is not limited to the above-described single-layer structure consisting of only the semi-transmissive layer. The counter-electrode CE may have a structure in which a transmissive layer is further stacked.

On the counter-electrode CE, where necessary, a light-transmissive insulation film, such as a silicon oxynitride (SiON) film, may be disposed. Such an insulation film is usable as a protection film for protecting the first to third organic EL elements OLED1 to OLED3, or as a film which adjusts the optical path length for optimizing optical interference.

Each organic layer ORG may include a thin film with an electron injection function, namely an electron injection layer, between the counter-electrode CE and the electron transport layer ETL. Such an electron injection layer can be formed of, e.g. lithium fluoride (LiF).

The structure of the electron transport layer ETL is not limited to the above-described single-layer structure, and it may be a multi-layer structure of two or more layers. Similarly, the structure of each of the first hole transport layer HTL1 and second hole transport layer HTL2 is not limited to the above-described single-layer structure, and it may be a multi-layer structure of two or more layers.

In addition, in the third organic EL element OLED3, the second hole transport layer HTL2 is disposed on the pixel electrode side of the first hole transport layer HTL1. Alternatively, the second hole transport layer HTL2 may be disposed on the counter-electrode side of the first hole transport layer HTL1.

The second hole transport layer HTL2, which is disposed only in the third organic EL element OLED3, is usable for the thickness adjustment of the entire device in order for the third organic EL element OLED3 to realize the device structure that makes use of the first-order interference. Thus, there may be a case in which the film thickness of the second hole transport layer HTL2 is greater than the film thickness of the first hole transport layer HTL1. In such a case, it is preferable to use a material, which is less expensive than the material of the first hole transport layer HTL1, as the material of the second hole transport layer HTL2.

In the structure in which the second hole transport layer HTL2 is disposed on the pixel electrode side of the first hole transport layer HTL1 as in the present embodiment, the first hole transport layer HTL1 and the second hole transport layer HTL2 are required to have different characteristics. Specifically, in the case where the second hole transport layer HTL2 for thickness adjustment is formed to be thicker than the first hole transport layer HTL1, it is preferable to use a material having such characteristics that the hole mobility is relatively high, as the material of the second hole transport layer HTL2. In particular, in the structure in which the first hole transport layer HTL1 is stacked on the second hole transport layer HTL2, it is preferable to form the second hole transport layer HTL2 by selecting a material having a higher hole mobility than the hole mobility of the first hole transport layer HTL1. On the other hand, it is preferable to form the first hole transport layer HTL1, which is in contact with the third light emission layer EM3, by selecting a material having such characteristics that the time-dependent variation is small, that is, a material having high stability.

Next, other examples of the present embodiment are described. In Examples 2 to Example 7 which are described below, each of the first organic EL element OLED1 and the second organic EL element OLED2 has the device structure which makes use of the 0th-order interference effect, and the third organic EL element OLED3 has the device structure which makes use of the first-order interference effect. The total film thickness between the reflective layer and the counter-electrode in each of the first to third organic EL elements OLED1 to OLED3 is the same as in Example 1.

### EXAMPLE 2

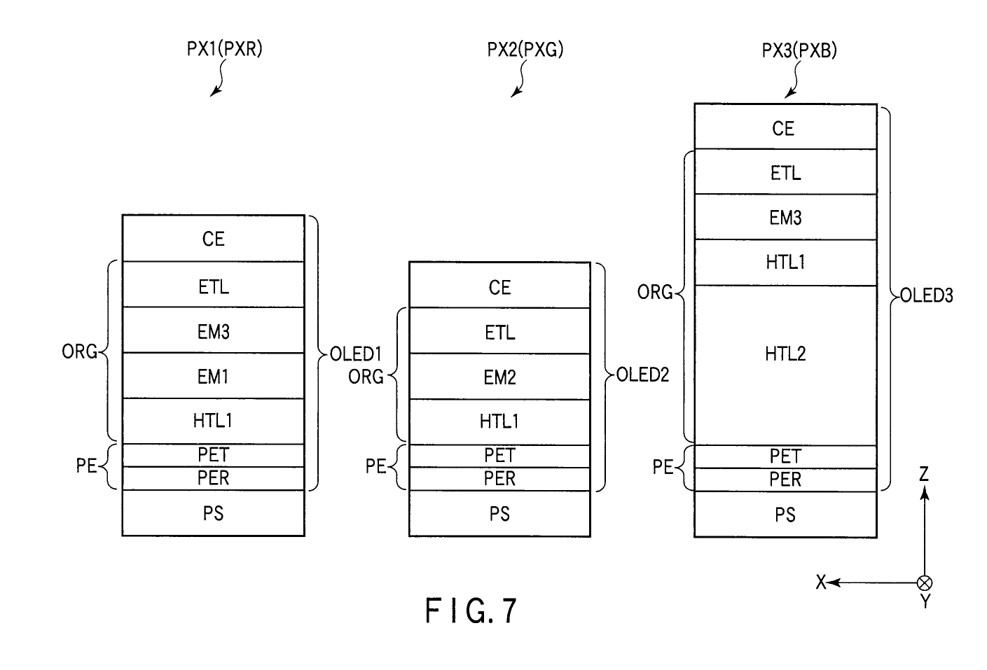

FIG. 7 schematically shows the structures of the first to third organic EL elements OLED1 to OLED3 in Example 2. Example 2 shown in FIG. 7 differs from Example 1 shown in FIG. 4 in that a third light emission layer EM3 is additionally provided between the first light emission layer EM1 and the electron transport layer ETL in the organic layer ORG of the first organic EL element OLED1. In the organic layer ORG of the first organic EL element OLED1, the third light emission layer EM3 is a hole blocking layer and emits no light.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a first hole transport layer HTL1, a first light emission layer EM1, a third light emission layer EM3 and an electron transport layer ETL are stacked in the named order between a reflective layer PER and a counter-electrode CE that is a semi-transmissive layer. In the second organic EL element OLED2, a transmissive layer PET, a first hole transport layer HTL1, a second light emission layer EM2 and an electron transport layer ETL are stacked in the named order between a reflective layer PER and a counter-electrode CE that is a semi-transmissive layer. In the third organic EL element OLED3, a transmissive layer PET, a second hole transport layer HTL2, a first hole transport layer HTL1, a third light emission layer EM3 and an electron transport layer ETL are stacked in the named order between a reflective layer PER and a counter-electrode CE that is a semi-transmissive layer.

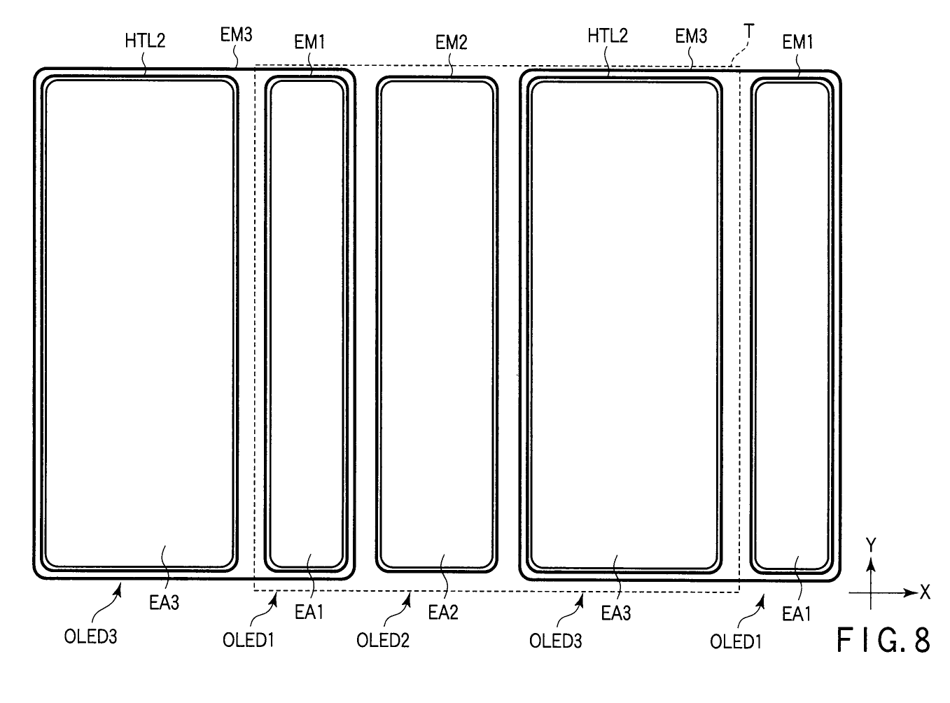

FIG. 8 schematically shows the first light emission layer EM1, second light emission layer EM2, third light emission layer EM3 and second hole transport layer HTL2, which are disposed in the triplet T in Example 2. Example 2 shown in FIG. 8 differs from Example 1 shown in FIG. 5 in that the third light emission layer EM3 is disposed over the light emission section EA1 of the first organic EL element OLED1 and the light emission section EA3 of the third organic EL element OLED3, which neighbor in the X direction.

The first light emission layer EM1 is disposed on an area which is equal to or greater than the area of the light emission section EA1 of the first organic EL element OLED1. The second light emission layer EM2 is disposed on an area which is equal to or greater than the area of the light emission section EA2 of the second organic EL element OLED2. The second hole transport layer HTL2 is disposed on an area which is equal to or greater than the area of the light emission section EA3 of the third organic EL element OLED3.

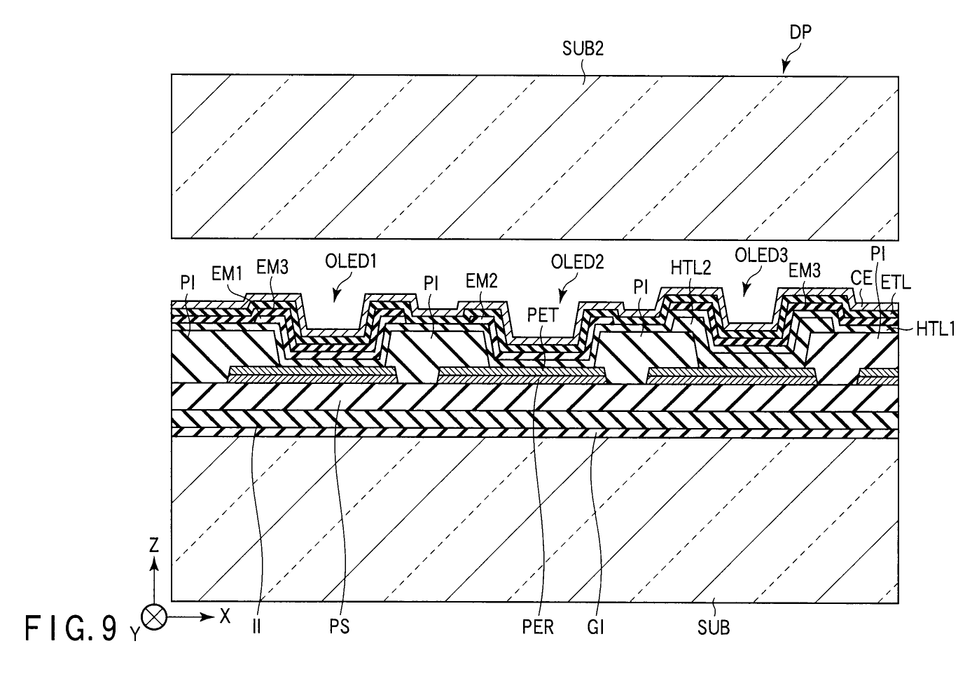

FIG. 9 schematically shows a cross-sectional structure of the display panel DP which includes the first to third organic EL elements OLED1 to OLED3 in Example 2. In FIG. 9, the dimensions in the X direction are different from those in FIG. 8 in order to clarify the structures of the first to third organic EL elements OLED1 to OLED3.

Example 2 shown in FIG. 9 differs from Example 1 shown in FIG. 6 in that the third light emission layer EM3 extends not only over the third organic EL element OLED3, but also over the first organic EL element OLED1.

The gate insulation film GI, interlayer insulation film II and passivation film PS are disposed between the substrate SUB and each reflective layer PER. The reflective layer PER and transmissive layer PET of each of the first to third organic EL elements OLED1 to OLED3 are disposed on the passivation film PS.

The second hole transport layer HTL2 is disposed on the transmissive layer PET of the third organic EL element OLED3. Part of the second hole transport layer HTL2 extends onto the partition wall PI which surrounds the third organic EL element OLED3.

As in Example 1, the first hole transport layer HTL1 is disposed over the first to third organic EL elements OLED1 to OLED3. The first hole transport layer HTL1 is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed on the first hole transport layer HTL1 of the first organic EL element OLED1. Part of the first light emission layer EM1 extends onto the partition wall PI surrounding the first organic EL element OLED1. The second light emission layer EM2 is disposed on the first hole transport layer HTL1 of the second organic EL element OLED2. Part of the second light emission layer EM2 extends onto the partition wall PI surrounding the second organic EL element OLED2.

The third light emission layer EM3 is disposed in the third organic EL element OLED3, and extends to the first organic EL element OLED1 which neighbors the third organic EL element OLED3 in the X direction. Specifically, the third light emission layer EM3 is disposed on the first light emission layer EM1 of the first organic EL element OLED1 and on the first hole transport layer HTL1 of the third organic EL element OLED3. In addition, the third light emission layer EM3 is disposed on the first hole transport layer HTL1 above the partition wall PI between the first organic EL element OLED1 and the third organic EL element OLED3. The third light emission layer EM3 in each of the first organic EL element OLED1 and third organic EL element OLED3 is formed of the same material in the same fabrication step, and has substantially equal film thickness.

As in Example 1, the electron transport layer ETL extends over the first to third organic EL elements OLED1 to OLED3. In addition, the electron transport layer ETL is disposed on the first hole transport layer HTL1 above the partition walls PI which are disposed between the first organic EL element OLED1 and the second organic EL element OLED2 and between the second organic EL element OLED2 and the third organic EL element OLED3. Further, the electron transport layer ETL is disposed on the third light emission layer EM3 above the partition wall PI which is disposed between the third organic EL element OLED3 and the first organic EL element OLED1.

The counter-electrode CE, as in Example 1, extends over the first to third organic EL elements OLED1 to OLED3, and is disposed on the electron transport layer ETL above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first to third organic EL elements OLED1 to OLED3 are sealed by using the sealing glass substrate SUB2.

The reflective layer PER, transmissive layer PET, first hole transport layer HTL1, second hole transport layer HTL2, first light emission layer EM1, second light emission layer EM2, third light emission layer EM3, electron transport layer ETL and counter-electrode CE can be formed of the same materials as in Example 1.

In Example 2, the same advantageous effects as in Example 1 can be obtained.

In addition, the third light emission layer EM3 is the continuous film spreading over the neighboring first organic EL element OLED1 and third organic EL element OLED3. Thus, when the third light emission layer EM3 is formed by evaporation deposition, use is made of a mask in which an opening connecting the neighboring light emission sections EA1 and EA3 is formed, instead of a fine mask in which a fine opening corresponding to the light emission section EA3 is formed. Specifically, the size of the opening in the mask can be increased, and the manufacturing cost of the mask can be reduced. Furthermore, the amount of material, which is deposited on the mask at the time of forming the third light emission layer EM3, decreases, and the efficiency of use of the material for forming the third light emission layer EM3 can be enhanced.

Furthermore, since the third light emission layer EM3, which is disposed in the first organic EL element OLED1, is usable for optical path length adjustment, the film thickness of the first light emission layer EM1 can be reduced by a degree corresponding to the film thickness of the third light emission layer EM3. Therefore, the amount of material that is used for forming the first light emission layer EM1 can be reduced, and the cost of material can be decreased.

According to Example 2, in the organic layer ORG of the first organic EL element OLED1, the third light emission layer EM3 is disposed between the first light emission layer EM1 and the electron transport layer ETL. The third light emission layer EM3 including the third light-emitting material, which has a wider band gap than the first light-emitting material of the first light emission layer EM1, functions as a hole blocking layer on the counter-electrode side of the first light emission layer EM1. Therefore, the carrier balance in the first organic EL element OLED1 can be improved, and the light emission efficiency can be improved.

In the first organic EL element OLED1, the first light emission layer EM1 including the first light-emitting material and the third light emission layer EM3 including the third light-emitting material are stacked. The first light-emitting material having the lowest excitation energy can emit light most easily from the excitation state. Accordingly, in the first organic EL element OLED1, the first light-emitting layer EM1 emits red light.

The second light-emitting material, too, has a wider band gap than the first light-emitting material. Thus, the organic layer ORG of the first organic EL element OLED1 may include a second light emission layer EM2 including the second light-emitting material, as a hole blocking layer, between the first light emission layer EM1 and the electron transport layer ETL. In this case, the second light emission layer EM2 extends over the first organic EL element OLED1 and second organic EL element OLED2 which neighbor in the X direction, and is also disposed on the first hole transport layer HTL1 above the partition wall PI which is disposed between the first organic EL element OLED1 and second organic EL element OLED2.

Besides, the organic layer ORG of the first organic EL element OLED1 may include a second light emission layer EM2 and a third light emission layer EM3, as hole blocking layers, between the first light emission layer EM1 and the electron transport layer ETL.

In short, it should suffice if the organic layer ORG of the first organic EL element OLED1 includes at least one of the second light emission layer EM2 and the third light emission layer EM3. In this case, at least one of the second light emission layer EM2 and the third light emission layer EM3 functions as a hole blocking layer in the first organic EL element OLED1.

However, the difference in band gap between the third light-emitting material and the first light-emitting material is greater than the difference in band gap between the second light-emitting material and the first light-emitting material. Thus, as the light emission layer that is stacked on the first light emission layer EM1, the third light emission layer EM3 including the third light-emitting material has a higher hole blocking effect than the second light emission layer EM2 including the second light-emitting material. It is desirable, therefore, to stack the third light emission layer EM3 on the first light emission layer EM1 in the first organic EL element OLED1.

In Example 2, all the device variations that have been described in Example 1 are applicable.

### EXAMPLE 3

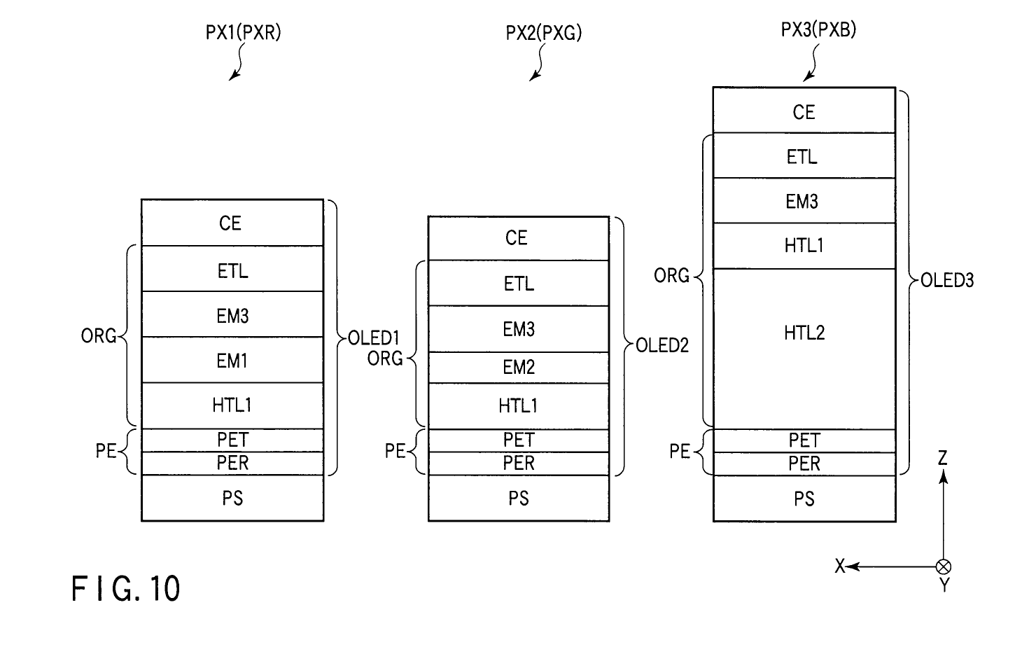

FIG. 10 schematically shows the structures of the first to third organic EL elements OLED1 to OLED3 in Example 3. Example 3 shown in FIG. 10 differs from Example 2 shown in FIG. 7 in that a third light emission layer EM3 is additionally provided between the second light emission layer EM2 and the electron transport layer ETL in the organic layer ORG of the second organic EL element OLED2. In the organic layers ORG of the first organic EL element OLED1 and second organic EL element OLED2, the third light emission layer EM3 emits no light.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a first hole transport layer HTL1, a first light emission layer EM1, a third light emission layer EM3 and an electron transport layer ETL are stacked in the named order between a reflective layer PER and a counter-electrode CE. In the second organic EL element OLED2, a transmissive layer PET, a first hole transport layer HTL1, a second light emission layer EM2, a third light emission layer EM3 and an electron transport layer ETL are stacked in the named order between a reflective layer PER and a counter-electrode CE. In the third organic EL element OLED3, a transmissive layer PET, a second hole transport layer HTL2, a first hole transport layer HTL1, a third light emission layer EM3 and an electron transport layer ETL are stacked in the named order between a reflective layer PER and a counter-electrode CE.

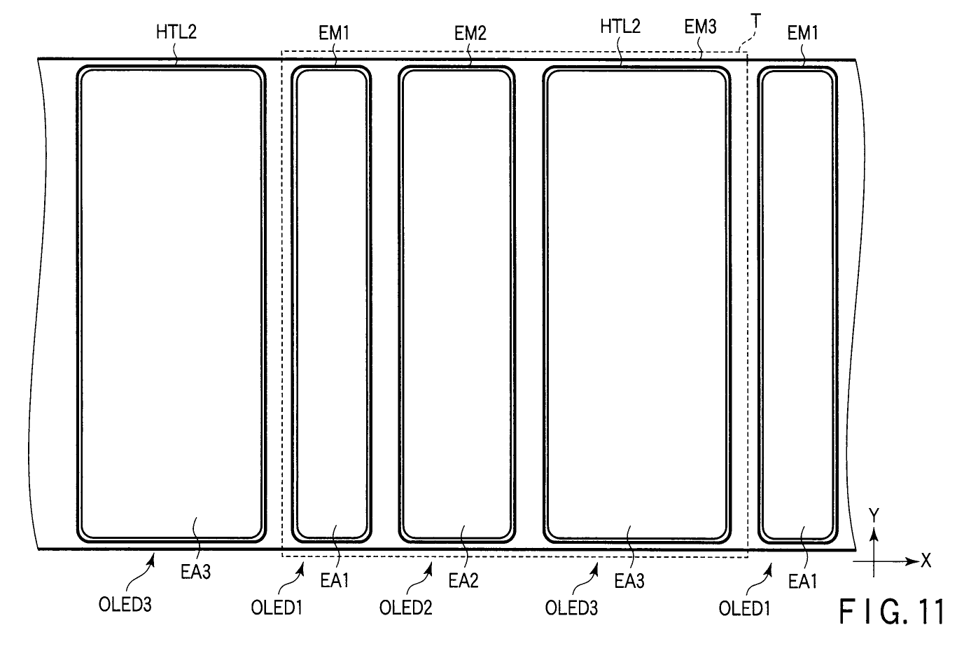

FIG. 11 schematically shows the first light emission layer EM1, second light emission layer EM2, third light emission layer EM3 and second hole transport layer HTL2, which are disposed in the triplet T in Example 3. Example 3 shown in FIG. 11 differs from Example 2 shown in FIG. 8 in that the third light emission layer EM3 is disposed over the light emission section EA1 of the first organic EL element OLED1, the light emission section EA2 of the second organic EL element OLED2 and the light emission section EA3 of the third organic EL element OLED3, which neighbor in the X direction.

The first light emission layer EM1 is disposed on an area which is equal to or greater than the area of the light emission section EA1 of the first organic EL element OLED1. The second light emission layer EM2 is disposed on an area which is equal to or greater than the area of the light emission section EA2 of the second organic EL element OLED2. The second hole transport layer HTL2 is disposed on an area which is equal to or greater than the area of the light emission section EA3 of the third organic EL element OLED3.

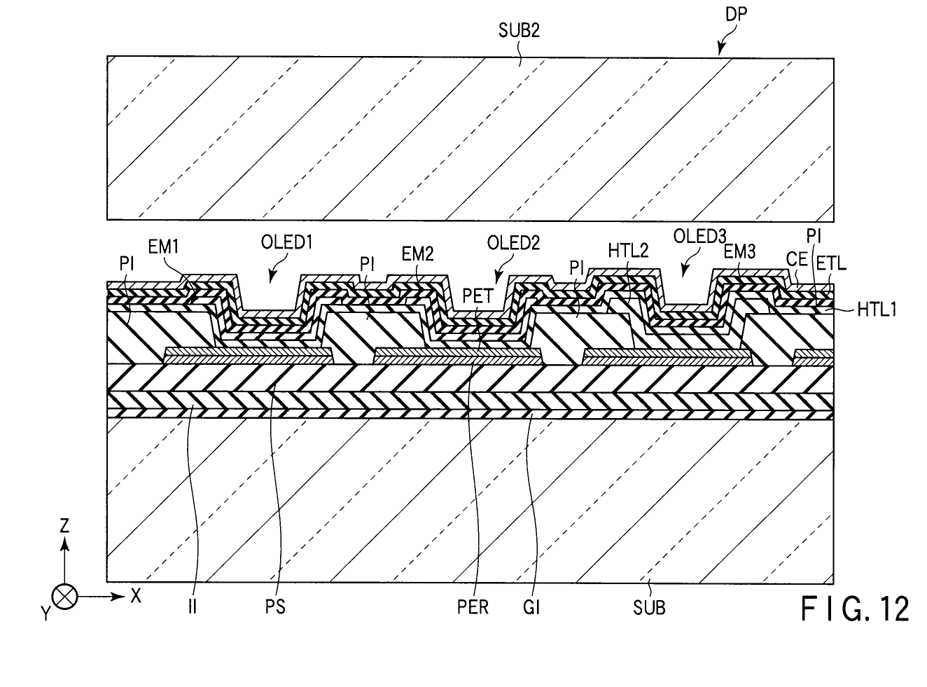

FIG. 12 schematically shows a cross-sectional structure of the display panel DP which includes the first to third organic EL elements OLED1 to OLED3 in Example 3. In FIG. 12, the dimensions in the X direction are different from those in FIG. 11 in order to clarify the structures of the first to third organic EL elements OLED1 to OLED3.

Example 3 shown in FIG. 12 differs from Example 2 shown in FIG. 9 in that the third light emission layer EM3 extends not only over the third organic EL element OLED3, but also over the first organic EL element OLED1 and second organic EL element OLED2.

The gate insulation film GI, interlayer insulation film II and passivation film PS are disposed between the substrate SUB and each reflective layer PER. The reflective layer PER and transmissive layer PET of each of the first to third organic EL elements OLED1 to OLED3 are disposed on the passivation film PS.

The second hole transport layer HTL2 is disposed on the transmissive layer PET of the third organic EL element OLED3. Part of the second hole transport layer HTL2 extends onto the partition wall PI which surrounds the third organic EL element OLED3.

The first hole transport layer HTL1 extends over the first to third organic EL elements OLED1 to OLED3, and is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed on the first hole transport layer HTL1 of the first organic EL element OLED1. Part of the first light emission layer EM1 extends onto the partition wall PI surrounding the first organic EL element OLED1. The second light emission layer EM2 is disposed on the first hole transport layer HTL1 of the second organic EL element OLED2. Part of the second light emission layer EM2 extends onto the partition wall PI surrounding the second organic EL element OLED2.

The third light emission layer EM3 extends over the first to third organic EL elements OLED1 to OLED3 which are arranged in the X direction. Specifically, the third light emission layer EM3 is disposed on the first light emission layer EM1 of the first organic EL element OLED1, on the second light emission layer EM2 of the second organic EL element OLED2, and on the first hole transport layer HTL1 of the third organic EL element OLED3. In addition, the third light emission layer EM3 is disposed on the first hole transport layer HTL1 above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1. The third light emission layer EM3 in each of the first to third organic EL elements OLED1 to OLED3 is formed of the same material in the same fabrication step, and has substantially equal film thickness.

The electron transport layer ETL extends over the first to third organic EL elements OLED1 to OLED3. In addition, the electron transport layer ETL is disposed on the third light emission layer EM3 above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The counter-electrode CE extends over the first to third organic EL elements OLED1 to OLED3, and is disposed on the electron transport layer ETL above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first to third organic EL elements OLED1 to OLED3 are sealed by using the sealing glass substrate SUB2.

The reflective layer PER, transmissive layer PET, first hole transport layer HTL1, second hole transport layer HTL2, first light emission layer EM1, second light emission layer EM2, third light emission layer EM3, electron transport layer ETL and counter-electrode CE can be formed of the same materials as in Example 1.

In Example 3, the same advantageous effects as in Example 2 can be obtained.

In addition, the third light emission layer EM3 is the continuous film spreading over the first to third organic EL elements OLED1 to OLED3. Thus, when the third light emission layer EM3 is formed by evaporation deposition, use is made of a mask in which an opening connecting the light emission sections EA1 to EA3 is formed, instead of a fine mask in which a fine opening corresponding to the light emission section EA3 is formed. Specifically, the size of the opening in the mask can be made still greater than in Example 2, and the manufacturing cost of the mask can be reduced. Furthermore, the amount of material, which is deposited on the mask at the time of forming the third light emission layer EM3, is still smaller than in Example 2, and the efficiency of use of the material for forming the third light emission layer EM3 can be enhanced.

Furthermore, the third light emission layer EM3, which is disposed in each of the first organic EL element OLED1 and second organic EL element OLED2, is usable for optical path length adjustment. Thus, in the first organic EL element OLED1, the film thickness of the first light emission layer EM1 can be reduced by a degree corresponding to the film thickness of the third light emission layer EM3. Similarly, in the second organic EL element OLED2, the film thickness of the second light emission layer EM2 can be reduced by a degree corresponding to the film thickness of the third light emission layer EM3. Therefore, the amount of material that is used for forming the first light emission layer EM1 and second light emission layer EM2 can be reduced, and the cost of material can be decreased.

In Example 3, all the device variations that have been described in Example 1 are applicable.

### EXAMPLE 4

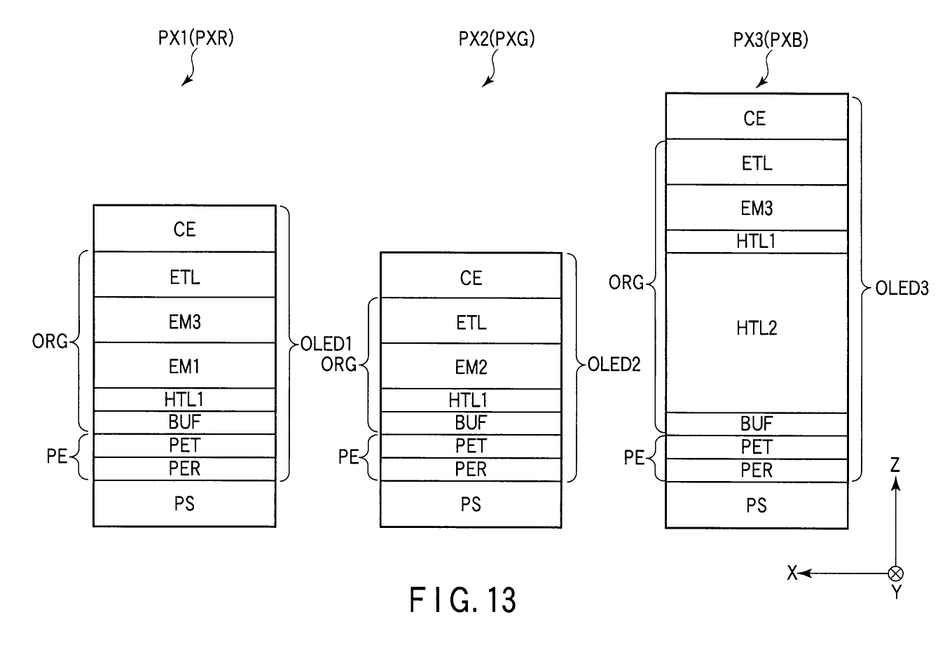

FIG. 13 schematically shows the structures of the first to third organic EL elements OLED1 to OLED3 in Example 4. Example 4 shown in FIG. 13 differs from Example 2 shown in FIG. 7 in that a buffer layer BUF is additionally provided between the pixel electrode PE and the first hole transport layer HTL1 in the organic layer ORG of each of the first organic EL element OLED1 and second organic EL element OLED2, and in that a buffer layer BUF is additionally provided between the pixel electrode PE and the second hole transport layer HTL2 in the organic layer ORG of the third organic EL element OLED3. In the organic layer ORG of the first organic EL element OLED1, the third light emission layer EM3 emits no light.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a buffer layer BUF, a first hole transport layer HTL1, a first light emission layer EM1, a third light emission layer EM3 and an electron transport layer ETL are stacked in the named order between a reflective layer PER and a counter-electrode CE. In the second organic EL element OLED2, a transmissive layer PET, a buffer layer BUF, a first hole transport layer HTL1, a second light emission layer EM2 and an electron transport layer ETL are stacked in the named order between a reflective layer PER and a counter-electrode CE. In the third organic EL element OLED3, a transmissive layer PET, a buffer layer BUF, a second hole transport layer HTL2, a first hole transport layer HTL1, a third light emission layer EM3 and an electron transport layer ETL are stacked in the named order between a reflective layer PER and a counter-electrode CE.

The layout of the first light emission layer EM1, second light emission layer EM2, third light emission layer EM3 and second hole transport layer HTL2, which are disposed in the triplet T in Example 4, is the same as the layout in Example 2, which is shown in FIG. 8. Thus, the depiction of this layout in Example 4 is omitted.

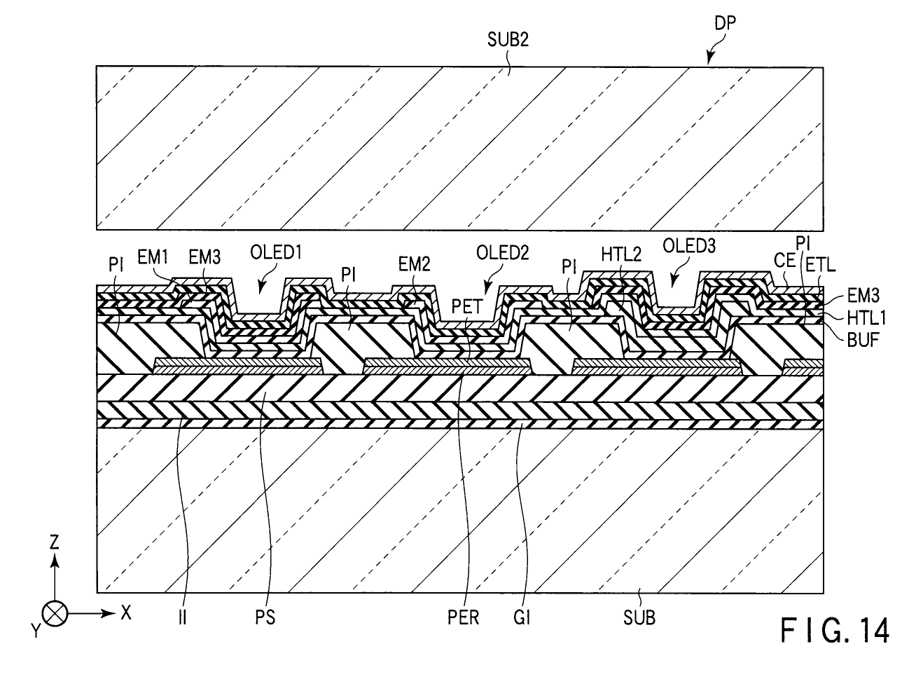

FIG. 14 schematically shows a cross-sectional structure of the display panel DP which includes the first to third organic EL elements OLED1 to OLED3 in Example 4. Example 4 shown in FIG. 14 differs from Example 2 shown in FIG. 9 in that the buffer layer BUF extends over the first to third organic EL elements OLED1 to OLED3. In the other structural aspects, Example 4 is the same as Example 2 shown in FIG. 9.

The first to third organic EL elements OLED1 to OLED3 in Example 4 can be fabricated in the procedure which is described below.

Specifically, the gate insulation film GI, interlayer insulation film II and passivation film PS are successively formed on the substrate SUB. The reflective layer PER and transmissive layer PET of each of the first to third organic EL elements OLED1 to OLED3 is formed on the passivation film PS. Then, partition walls PI surrounding the transmissive layers PET of the first to third organic EL elements OLED1 to OLED3 are formed.

Subsequently, using a rough mask, a buffer layer BUF is formed over the first to third organic EL elements OLED1 to OLED3. The buffer layer BUF has at least a hole injection function, and is subjected to a reflowing process after the buffer layer BUF is formed on the transmissive layers PET and partition walls PI.

Then, using a fine mask having an opening corresponding to the third organic EL element OLED3, a second hole transport layer HTL2 is formed on the buffer layer BUF in the third organic EL element OLED3.

Thereafter, using a rough mask, a first hole transport layer HTL1 is formed over the first to third organic EL elements OLED1 to OLED3.

Subsequently, using a fine mask having an opening corresponding to the first organic EL element OLED1, a first light emission layer EM1 is formed on the first hole transport layer HTL1 in the first organic EL element OLED1. In addition, using a fine mask having an opening corresponding to the second organic EL element OLED2, a second light emission layer EM2 is formed on the first hole transport layer HTL1 in the second organic EL element OLED2.

Using a mask having an opening connecting the first organic EL element OLED1 and third organic EL element OLED3 which neighbor in the X direction, a third light emission layer EM3 is formed on the first light emission layer EM1 in the first organic EL element OLED1 and on the first hole transport layer HTL1 in the third organic EL element OLED3.

Following the above, using a rough mask, an electron transport layer ETL is formed over the first to third organic EL elements OLED1 to OLED3. Thereafter, using a rough mask, a counter-electrode CE is formed over the first to third organic EL elements OLED1 to OLED3.

The first to third organic EL elements OLED1 to OLED3, which have thus been formed, are sealed by using a sealing glass substrate SUB2.

The reflective layer PER, transmissive layer PET, first hole transport layer HTL1, second hole transport layer HTL2, first light emission layer EM1, second light emission layer EM2, third light emission layer EM3, electron transport layer ETL and counter-electrode CE can be formed of the same materials as in Example 1.

In Example 4, the same advantageous effects as in Example 2 can be obtained.

In addition, by the reflowing process, the buffer layer BUF has a function of reducing the influence of foreign matter on the surface of the pixel electrode PE. Thereby, short-circuit between electrodes and the occurrence of film defects can be suppressed.

The buffer layer BUF is a continuous film spreading over the first to third organic EL elements OLED1 to OLED3. Thus, when the buffer layer BUF is formed by evaporation deposition, use is made of a mask in which an opening connecting the light emission sections EA1 to EA3 is formed. In short, a fine mask for forming the buffer layer BUF is not needed.

Furthermore, the buffer layer BUF, which is disposed in the first to third organic EL elements OLED1 to OLED3, is usable for optical path length adjustment. Thus, in the first organic EL element OLED1 and second organic EL element OLED2, the film thickness of the first hole transport layer HTL1 can be reduced by a degree corresponding to the film thickness of the buffer layer BUF. Similarly, in the third organic EL element OLED3, the film thickness of the first hole transport layer HTL1 and second hole transport layer HTL2 can be reduced by a degree corresponding to the film thickness of the buffer layer BUF. Therefore, the amount of material that is used for forming the first hole transport layer HTL1 and second hole transport layer HTL2 can be reduced, and the cost of material can be decreased.

In Example 4, all the device variations that have been described in Example 1 are applicable.

### EXAMPLE 5

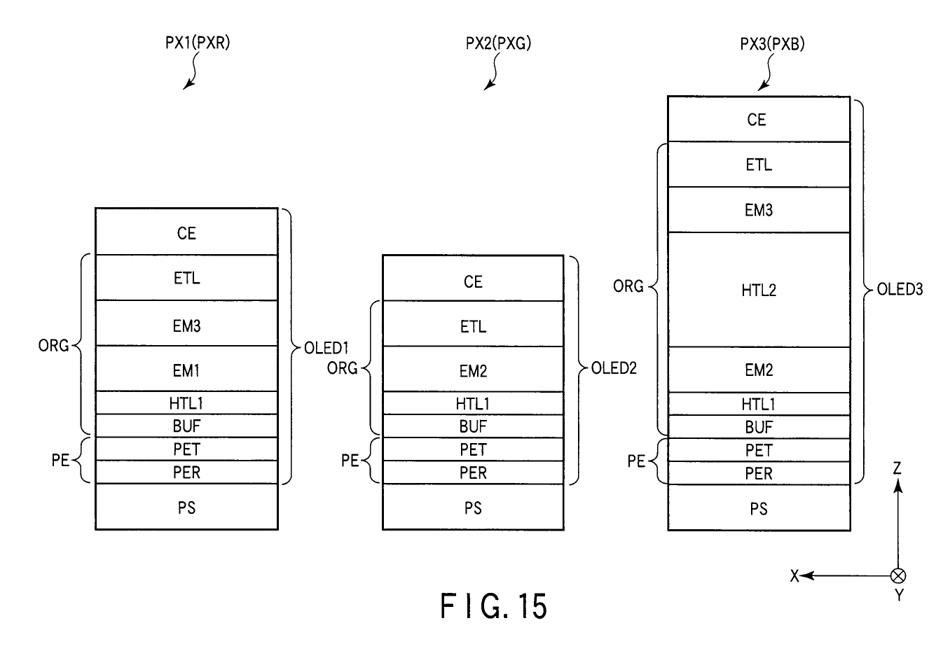

FIG. 15 schematically shows the structures of the first to third organic EL elements OLED1 to OLED3 in Example 5. Example 5 shown in FIG. 15 differs from Example 4 shown in FIG. 13 in that a second light emission layer EM2 is additionally provided in the organic layer ORG of the third organic EL element OLED3, and in that the second hole transport layer HTL2 is disposed between the second light emission layer EM2 and third light emission layer EM3. In the organic layer ORG of the first organic EL element OLED1, the third light emission layer EM3 emits no light. In addition, in the organic layer ORG of the third organic EL element OLED3, the second light emission layer EM2 emits no light.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a buffer layer BUF, a first hole transport layer HTL1, a first light emission layer EM1, a third light emission layer EM3 and an electron transport layer ETL are stacked in the named order between a reflective layer PER and a counter-electrode CE. In the second organic EL element OLED2, a transmissive layer PET, a buffer layer BUF, a first hole transport layer HTL1, a second light emission layer EM2 and an electron transport layer ETL are stacked in the named order between a reflective layer PER and a counter-electrode CE. In the third organic EL element OLED3, a transmissive layer PET, a buffer layer BUF, a first hole transport layer HTL1, a second light emission layer EM2, a second hole transport layer HTL2, a third light emission layer EM3 and an electron transport layer ETL are stacked in the named order between a reflective layer PER and a counter-electrode CE.

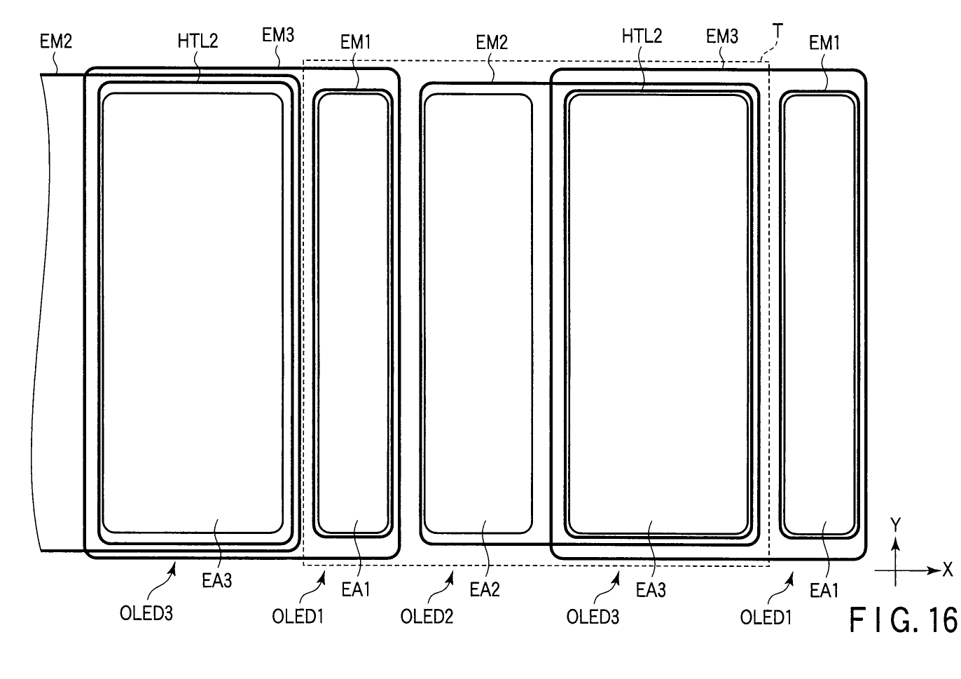

FIG. 16 schematically shows the first light emission layer EM1, second light emission layer EM2, third light emission layer EM3 and second hole transport layer HTL2, which are disposed in the triplet T in Example 5. Example 5 shown in FIG. 16 differs from Example 4 in that the second light emission layer EM2 is disposed over the light emission section EA2 of the second organic EL element OLED2 and the light emission section EA3 of the third organic EL element OLED3, which neighbor in the X direction.

The first light emission layer EM1 is disposed on an area which is equal to or greater than the area of the light emission section EA1 of the first organic EL element OLED1. The third light emission layer EM3 is disposed over the light emission section EA3 of the third organic EL element OLED3 and the light emission section EA1 of the first organic EL element OLED1, which neighbor in the X direction. The second hole transport layer HTL2 is disposed on an area which is equal to or greater than the area of the light emission section EA3 of the third organic EL element OLED3.

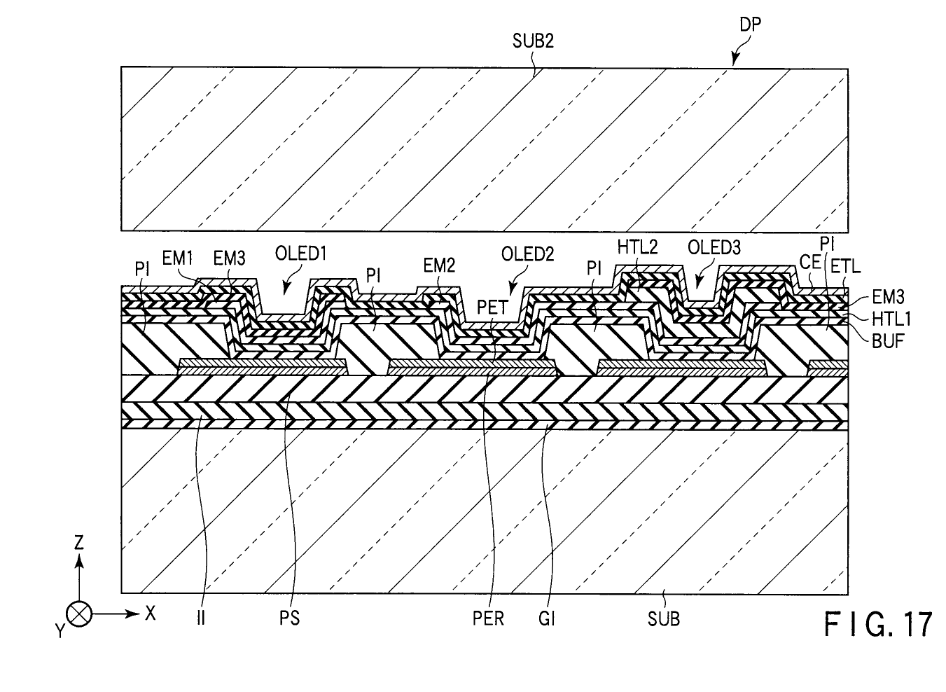

FIG. 17 schematically shows a cross-sectional structure of the display panel DP which includes the first to third organic EL elements OLED1 to OLED3 in Example 5. In FIG. 17, the dimensions in the X direction are different from those in FIG. 16 in order to clarify the structures of the first to third organic EL elements OLED1 to OLED3.

Example 5 shown in FIG. 17 differs from Example 4 shown in FIG. 14 in that the second light emission layer EM2 extends not only over the second organic EL element OLED2, but also over the third organic EL element OLED3.

The gate insulation film GI, interlayer insulation film II and passivation film PS are disposed between the substrate SUB and each reflective layer PER. The reflective layer PER and transmissive layer PET of each of the first to third organic EL elements OLED1 to OLED3 are disposed on the passivation film PS.

The buffer layer BUF extends over the first to third organic EL elements OLED1 to OLED3, and is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first hole transport layer HTL1 extends over the first to third organic EL elements OLED1 to OLED3, and is disposed on the buffer layer BUF above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed on the first hole transport layer HTL1 of the first organic EL element OLED1. Part of the first light emission layer EM1 extends onto the partition wall PI surrounding the first organic EL element OLED1.

The second light emission layer EM2 is disposed in the second organic EL element OLED2, and extends to the third organic EL element OLED3 which neighbors the second organic EL element OLED2 in the X direction. Specifically, the second light emission layer EM2 is disposed on the first hole transport layer HTL1 of each of the second organic EL element OLED2 and the third organic EL element OLED3. In addition, the second light emission layer EM2 is disposed on the first hole transport layer HTL1 above the partition wall PI which is disposed between the second organic EL element OLED2 and the third organic EL element OLED3. The second light emission layer EM2 in each of the second organic EL element OLED2 and the third organic EL element OLED3 is formed of the same material in the same fabrication step, and has substantially equal film thickness.

The second hole transport layer HTL2 is disposed on the second light transmission layer EM2 of the third organic EL element OLED3. Part of the second hole transport layer HTL2 extends onto the partition wall PI which surrounds the third organic EL element OLED3.

The third light emission layer EM3 extends over the first organic EL element OLED1 and the third organic EL element OLED3 which are arranged in the X direction. Specifically, the third light emission layer EM3 is disposed on the first light emission layer EM1 of the first organic EL element OLED1, and on the second hole transport layer HTL2 of the third organic EL element OLED3. In addition, the third light emission layer EM3 is disposed on the first hole transport layer HTL1 above the partition wall PI which is disposed between the first organic EL element OLED1 and the third organic EL element OLED3. The third light emission layer EM3 in each of the first organic EL element OLED1 and third organic EL element OLED3 is formed of the same material in the same fabrication step, and has substantially equal film thickness.

The electron transport layer ETL extends over the first to third organic EL elements OLED1 to OLED3. In addition, the electron transport layer ETL is disposed on the first hole transport layer HTL1 above the partition wall PI which is disposed between the first organic EL element OLED1 and the second organic EL element OLED2. In addition, the electron transport layer ETL is disposed on the second light emission layer EM2 above the partition wall PI which is disposed between the second organic EL element OLED2 and the third organic EL element OLED3. Further, the electron transport layer ETL is disposed on the third light emission layer EM3 above the partition wall PI which is disposed between the third organic EL element OLED3 and the first organic EL element OLED1.

The counter-electrode CE extends over the first to third organic EL elements OLED1 to OLED3, and is disposed on the electron transport layer ETL above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first to third organic EL elements OLED1 to OLED3 are sealed by using the sealing glass substrate SUB2.

In Example 5, the same advantageous effects as in Example 4 can be obtained.

In addition, the second light emission layer EM2 is the continuous film spreading over the second organic EL element OLED2 and third organic EL element OLED3. Thus, when the second light emission layer EM2 is formed by evaporation deposition, use is made of a mask in which an opening connecting the light emission sections EA2 and EA3 is formed, instead of a fine mask in which a fine opening corresponding to the light emission section EA2 is formed. Specifically, the size of the opening in the mask can be increased, and the manufacturing cost of the mask can be reduced. Furthermore, the amount of material, which is deposited on the mask at the time of forming the second light emission layer EM2, decreases, and the efficiency of use of the material for forming the second light emission layer EM2 can be enhanced.

In addition, since the second light emission layer EM2, which is disposed in the third organic EL element OLED3, is usable for optical path length adjustment, the film thickness of the second hole transport layer HTL2 can be reduced by a degree corresponding to the film thickness of the second light emission layer EM2. Therefore, the amount of material that is used for forming the second hole transport layer HTL2 can be reduced, and the cost of material can be decreased.

Moreover, the organic layer ORG of the third organic EL element OLED3 includes the second light emission layer EM2 on the pixel electrode side of the third light emission layer EM3. Since the second light emission layer EM2 is disposed between the first hole transport layer HTL1 and second hole transport layer HTL2, the second light emission layer EM2 is formed of a material with hole transport properties. Specifically, in Example 5, the second light emission layer EM2 including the second light-emitting material, which emits green light, functions as a third hole transport layer. By selecting the material with hole transport properties as the material of which the second light emission layer EM2 is formed, the hole transport from the pixel electrode PE to the third light emission layer EM3 is not hindered, and it is possible to prevent an increase in driving voltage and a decrease in light emission efficiency in the third organic EL element OLED3.

In Example 5, all the device variations that have been described in Example 1 are applicable.

### EXAMPLE 6

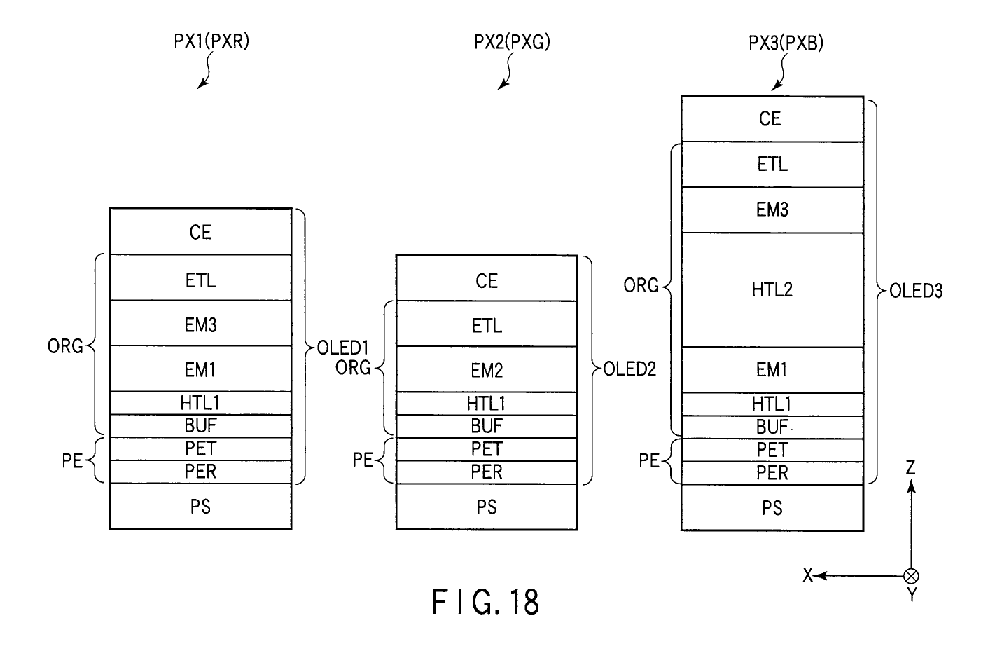

FIG. 18 schematically shows the structures of the first to third organic EL elements OLED1 to OLED3 in Example 6. Example 6 shown in FIG. 18 differs from Example 4 shown in FIG. 13 in that a first light emission layer EM1 is additionally provided in the organic layer ORG of the third organic EL element OLED3, and in that the second hole transport layer HTL2 is disposed between the first light emission layer EM1 and third light emission layer EM3. In the organic layer ORG of the first organic EL element OLED1, the third light emission layer EM3 emits no light. In addition, in the organic layer ORG of the third organic EL element OLED3, the first light emission layer EM1 emits no light.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a buffer layer BUF, a first hole transport layer HTL1, a first light emission layer EM1, a third light emission layer EM3 and an electron transport layer ETL are stacked in the named order between a reflective layer PER and a counter-electrode CE. In the second organic EL element OLED2, a transmissive layer PET, a buffer layer BUF, a first hole transport layer HTL1, a second light emission layer EM2 and an electron transport layer ETL are stacked in the named order between a reflective layer PER and a counter-electrode CE. In the third organic EL element OLED3, a transmissive layer PET, a buffer layer BUF, a first hole transport layer HTL1, a first light emission layer EM1, a second hole transport layer HTL2, a third light emission layer EM3 and an electron transport layer ETL are stacked in the named order between a reflective layer PER and a counter-electrode CE.

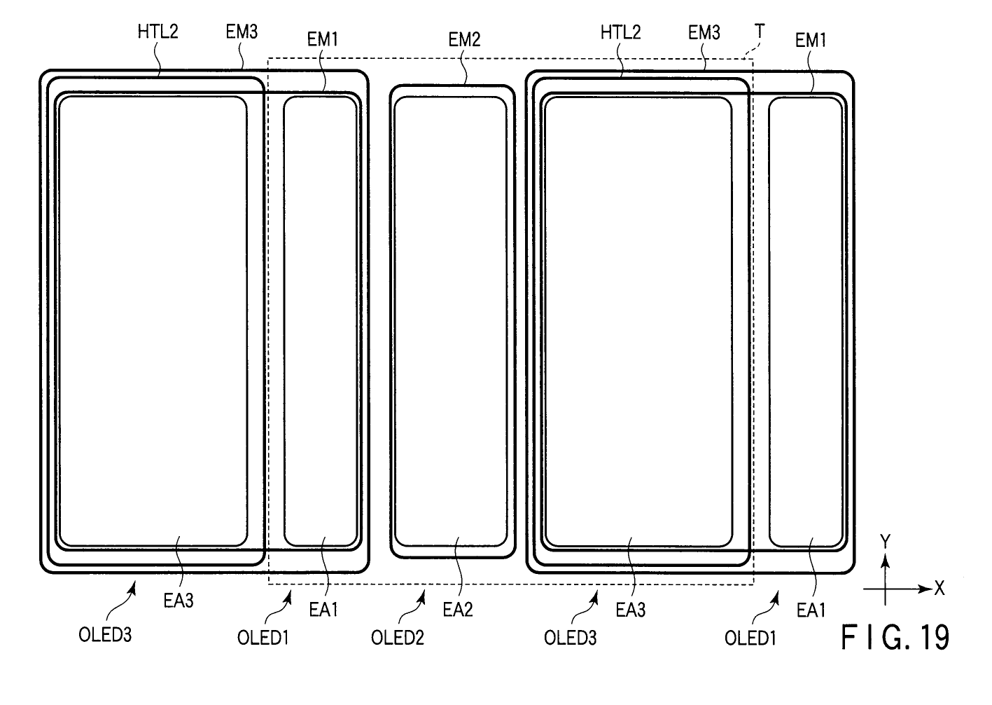

FIG. 19 schematically shows the first light emission layer EM1, second light emission layer EM2, third light emission layer EM3 and second hole transport layer HTL2, which are disposed in the triplet T in Example 6. Example 6 shown in FIG. 19 differs from Example 4 in that the first light emission layer EM1 is disposed over the light emission section EA1 of the first organic EL element OLED1 and the light emission section EA3 of the third organic EL element OLED3, which neighbor in the X direction.

The second light emission layer EM2 is disposed on an area which is equal to or greater than the area of the light emission section EA2 of the second organic EL element OLED2. The third light emission layer EM3 is disposed over the light emission section EA3 of the third organic EL element OLED3 and the light emission section EA1 of the first organic EL element OLED1, which neighbor in the X direction. The second hole transport layer HTL2 is disposed on an area which is equal to or greater than the area of the light emission section EA3 of the third organic EL element OLED3.

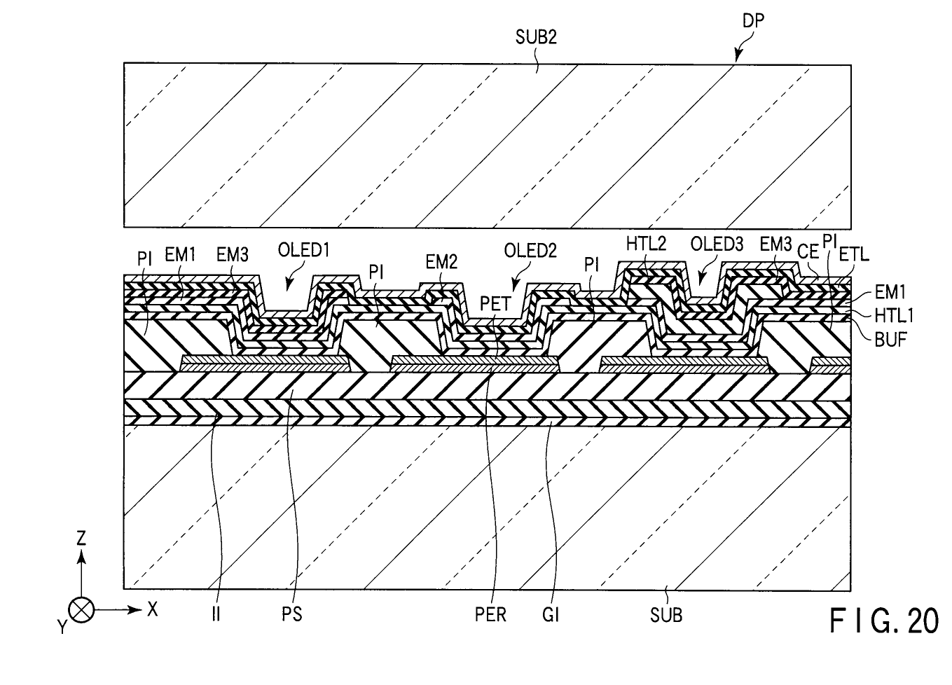

FIG. 20 schematically shows a cross-sectional structure of the display panel DP which includes the first to third organic EL elements OLED1 to OLED3 in Example 6. In FIG. 20, the dimensions in the X direction are different from those in FIG. 19 in order to clarify the structures of the first to third organic EL elements OLED1 to OLED3.

Example 6 shown in FIG. 20 differs from Example 4 shown in FIG. 14 in that the first light emission layer EM1 extends not only over the first organic EL element OLED1, but also over the third organic EL element OLED3.

The gate insulation film GI, interlayer insulation film II and passivation film PS are disposed between the substrate SUB and each reflective layer PER. The reflective layer PER and transmissive layer PET of each of the first to third organic EL elements OLED1 to OLED3 are disposed on the passivation film PS.

The buffer layer BUF extends over the first to third organic EL elements OLED1 to OLED3, and is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first hole transport layer HTL1 extends over the first to third organic EL elements OLED1 to OLED3, and is disposed on the buffer layer BUF above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed in the first organic EL element OLED1, and extends to the third organic EL element OLED3 which neighbors the first organic EL element OLED1 in the X direction. Specifically, the first light emission layer EM1 is disposed on the first hole transport layer HTL1 of each of the first organic EL element OLED1 and the third organic EL element OLED3. In addition, the first light emission layer EM1 is disposed on the first hole transport layer HTL1 above the partition wall PI which is disposed between the first organic EL element OLED1 and the third organic EL element OLED3. The first light emission layer EM1 in each of the first organic EL element OLED1 and the third organic EL element OLED3 is formed of the same material in the same fabrication step, and has substantially equal film thickness.

The second light emission layer EM2 is disposed on the first hole transport layer HTL1 of the second organic EL element OLED2. Part of the second light emission layer EM2 extends onto the partition wall PI surrounding the second organic EL element OLED2.

The second hole transport layer HTL2 is disposed on the first light transmission layer EM1 of the third organic EL element OLED3. Part of the second hole transport layer HTL2 extends onto the partition wall PI which surrounds the third organic EL element OLED3.

The third light emission layer EM3 extends over the first organic EL element OLED1 and the third organic EL element OLED3 which are arranged in the X direction. Specifically, the third light emission layer EM3 is disposed on the first light emission layer EM1 of the first organic EL element OLED1, and on the second hole transport layer HTL2 of the third organic EL element OLED3. In addition, the third light emission layer EM3 is disposed on the first emission layer EM1 above the partition wall PI which is disposed between the first organic EL element OLED1 and the third organic EL element OLED3. The third light emission layer EM3 in each of the first organic EL element OLED1 and third organic EL element OLED3 is formed of the same material in the same fabrication step, and has substantially equal film thickness.

The electron transport layer ETL extends over the first to third organic EL elements OLED1 to OLED3. In addition, the electron transport layer ETL is disposed on the first hole transport layer HTL1 above the partition walls PI which are disposed between the first organic EL element OLED1 and the second organic EL element OLED2 and between the second organic EL element OLED2 and the third organic EL element OLED3. In addition, the electron transport layer ETL is disposed on the third light emission layer EM3 above the partition wall PI which is disposed between the third organic EL element OLED3 and the first organic EL element OLED1.

The counter-electrode CE extends over the first to third organic EL elements OLED1 to OLED3, and is disposed on the electron transport layer ETL above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first to third organic EL elements OLED1 to OLED3 are sealed by using the sealing glass substrate SUB2.

In Example 6, the same advantageous effects as in Example 4 can be obtained.

In addition, the first light emission layer EM1 is the continuous film spreading over the first organic EL element OLED1 and third organic EL element OLED3. Thus, when the first light emission layer EM1 is formed by evaporation deposition, use is made of a mask in which an opening connecting the light emission sections EA1 and EA3 is formed, instead of a fine mask in which a fine opening corresponding to the light emission section EA1 is formed. Specifically, the size of the opening in the mask can be increased, and the manufacturing cost of the mask can be reduced. Furthermore, the amount of material, which is deposited on the mask at the time of forming the first light emission layer EM1, decreases, and the efficiency of use of the material for forming the first light emission layer EM1 can be enhanced.

In this Example 6, the minimum opening size of the fine mask which is needed for forming the first to third organic EL elements OLED1 to OLED3 is substantially equal to the size of the light emission section EA2. Specifically, of the layers which constitute the organic layer ORG that is formed by evaporation deposition, the layers other than the second light emission layer EM2 and second hole transport layer HTL2 extend over two or more organic EL elements. On the other hand, the second light emission layer EM2 is formed on the area that is substantially equal to the area of the light emission section EA2, and the second hole transport layer HTL2 is formed on the area that is substantially equal to the area of the light emission section EA3. As has been described above, the area of the light emission section EA3 is greater than the area of the light emission section EA2, and the area of the light emission section EA2 is greater than the area of the light emission section EA1. Thus, the minimum opening size of the fine mask, which is used in Example 6, is substantially equal to the area of the light emission section EA2, and the minimum opening size can be made greater, compared to the other Examples. Therefore, the structure of Example 6 is advantageous in achieving higher fineness.

Furthermore, since the first light emission layer EM1, which is disposed in the third organic EL element OLED3, is usable for optical path length adjustment, the film thickness of the second hole transport layer HTL2 can be reduced by a degree corresponding to the film thickness of the first light emission layer EM1. Therefore, the amount of material that is used for forming the second hole transport layer HTL2 can be reduced, and the cost of material can be decreased.

Moreover, the organic layer ORG of the third organic EL element OLED3 includes the first light emission layer EM1 on the pixel electrode side of the third light emission layer EM3. Since the first light emission layer EM1 is disposed between the first hole transport layer HTL1 and second hole transport layer HTL2, the first light emission layer EM1 is formed of a material with hole transport properties. Specifically, in Example 6, the first light emission layer EM1 including the first light-emitting material, which emits red light, functions as a third hole transport layer. By selecting the material with hole transport properties as the material of which the first light emission layer EM1 is formed, the hole transport from the pixel electrode PE to the third light emission layer EM3 is not hindered, and it is possible to prevent an increase in driving voltage and a decrease in light emission efficiency in the third organic EL element OLED3.

In Example 6, all the device variations that have been described in Example 1 are applicable.

### EXAMPLE 7

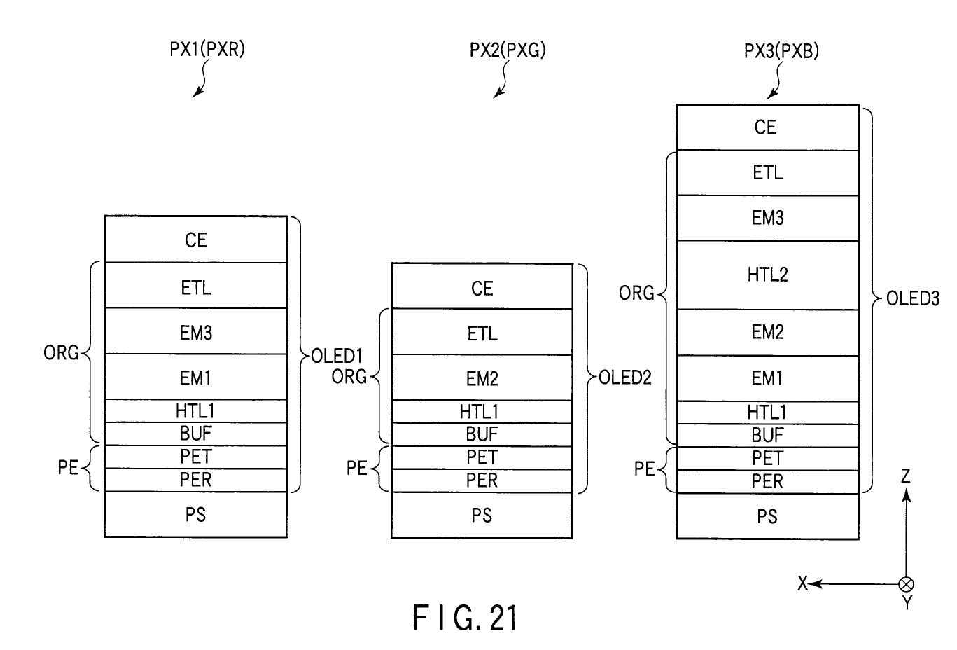

FIG. 21 schematically shows the structures of the first to third organic EL elements OLED1 to OLED3 in Example 7. Example 7 shown in FIG. 21 differs from Example 6 shown in FIG. 18 in that a second light emission layer EM2 is additionally provided between the first light emission layer EM1 and the second hole transport layer HTL2 in the organic layer ORG of the third organic EL element OLED3. In the organic layer ORG of the first organic EL element OLED1, the third light emission layer EM3 emits no light. In addition, in the organic layer ORG of the third organic EL element OLED3, the first light emission layer EM1 and second light emission layer EM2 emit no light.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a buffer layer BUF, a first hole transport layer HTL1, a first light emission layer EM1, a third light emission layer EM3 and an electron transport layer ETL are stacked in the named order between a reflective layer PER and a counter-electrode CE. In the second organic EL element OLED2, a transmissive layer PET, a buffer layer BUF, a first hole transport layer HTL1, a second light emission layer EM2 and an electron transport layer ETL are stacked in the named order between a reflective layer PER and a counter-electrode CE. In the third organic EL element OLED3, a transmissive layer PET, a buffer layer BUF, a first hole transport layer HTL1, a first light emission layer EM1, a second light transmission layer EM2, a second hole transport layer HTL2, a third light emission layer EM3 and an electron transport layer ETL are stacked in the named order between a reflective layer PER and a counter-electrode CE.

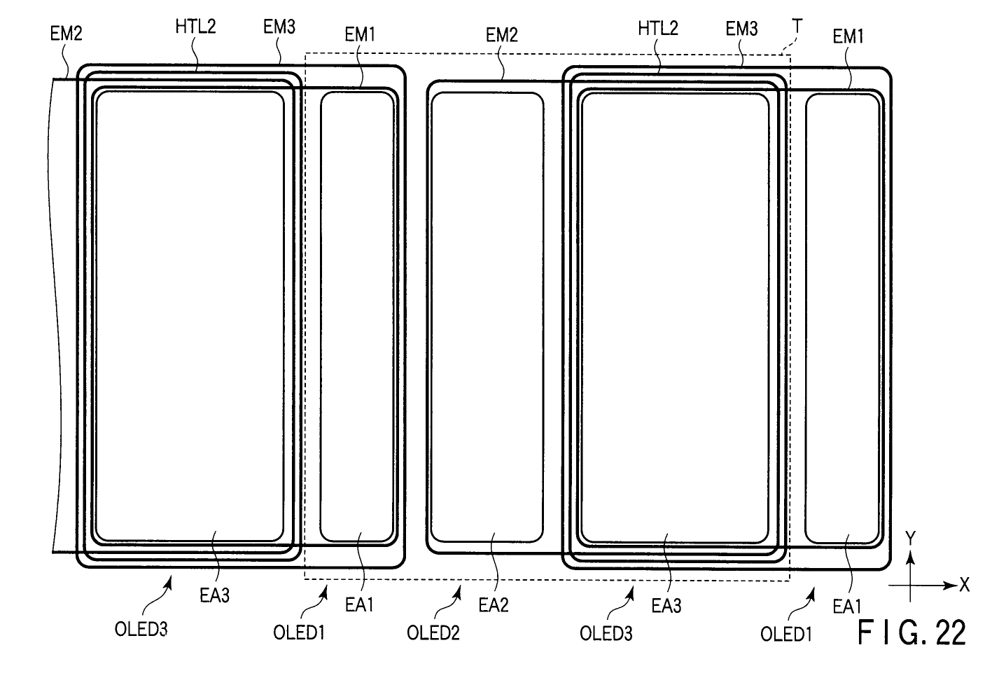

FIG. 22 schematically shows the first light emission layer EM1, second light emission layer EM2, third light emission layer EM3 and second hole transport layer HTL2, which are disposed in the triplet T in Example 7. Example 7 shown in FIG. 22 differs from Example 6 shown in FIG. 19 in that the second light emission layer EM2 is disposed over the light emission section EA2 of the second organic EL element OLED2 and the light emission section EA3 of the third organic EL element OLED3, which neighbor in the X direction.

The first light emission layer EM1 and the third light emission layer EM3 are disposed over the light emission section EA3 of the third organic EL element OLED3 and the light emission section EA1 of the first organic EL element OLED1, which neighbor in the X direction. The second hole transport layer HTL2 is disposed on an area which is equal to or greater than the area of the light emission section EA3 of the third organic EL element OLED3.

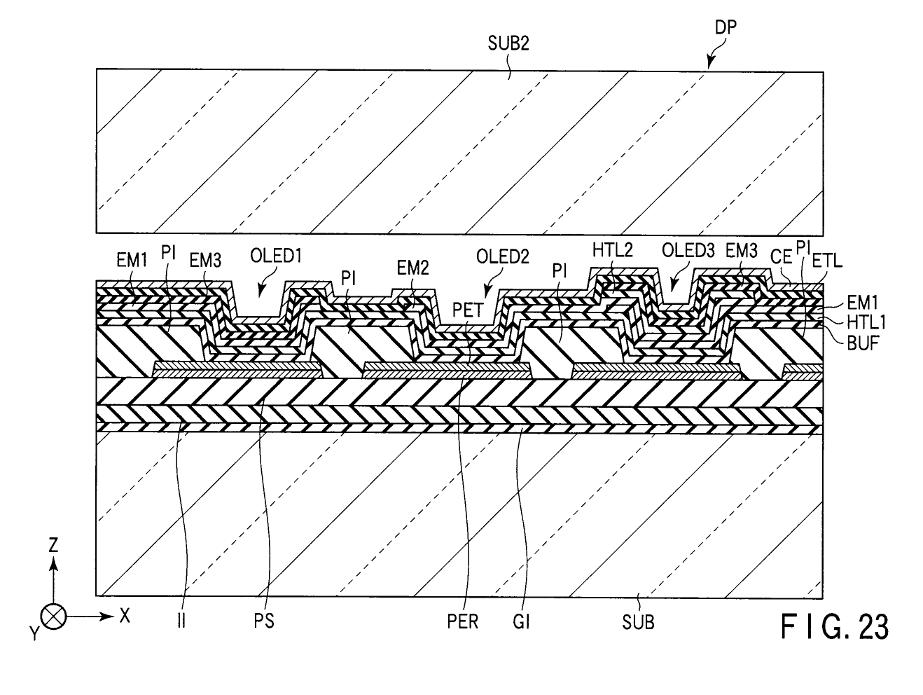

FIG. 23 schematically shows a cross-sectional structure of the display panel DP which includes the first to third organic EL elements OLED1 to OLED3 in Example 7. In FIG. 23, the dimensions in the X direction are different from those in FIG. 22 in order to clarify the structures of the first to third organic EL elements QLED1 to OLED3.

Example 7 shown in FIG. 23 differs from Example 6 shown in FIG. 20 in that the second light emission layer EM2 extends not only over the second organic EL element OLED2, but also over the third organic EL element OLED3.

The gate insulation film GI, interlayer insulation film II and passivation film PS are disposed between the substrate SUB and each reflective layer PER. The reflective layer PER and transmissive layer PET of each of the first to third organic EL elements OLED1 to OLED3 are disposed on the passivation film PS.

The buffer layer BUF extends over the first to third organic EL elements OLED1 to OLED3, and is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first hole transport layer HTL1 extends over the first to third organic EL elements OLED1 to OLED3, and is disposed on the buffer layer BUF above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed in the first organic EL element OLED1, and extends to the third organic EL element OLED3 which neighbors the first organic EL element OLED1 in the X direction. Specifically, the first light emission layer EM1 is disposed on the first hole transport layer HTL1 of each of the first organic EL element OLED1 and the third organic EL element OLED3. In addition, the first light emission layer EM1 is disposed on the first hole transport layer HTL1 above the partition wall PI which is disposed between the first organic EL element OLED1 and the third organic EL element OLED3. The first light emission layer EM1 in each of the first organic EL element OLED1 and the third organic EL element OLED3 is formed of the same material in the same fabrication step, and has substantially equal film thickness.

The second light emission layer EM2 is disposed in the second organic EL element OLED2, and extends to the third organic EL element OLED3 which neighbors the second organic EL element OLED2 in the X direction. Specifically, the second light emission layer EM2 is disposed on the first hole transport layer HTL1 of the second organic EL element OLED2 and on the first light emission layer EM1 of the third organic EL element OLED3. In addition, the second light emission layer EM2 is disposed on the first hole transport layer HTL1 above the partition wall PI which is disposed between the second organic EL element OLED2 and the third organic EL element OLED3. The second light emission layer EM2 in each of the second organic EL element OLED2 and the third organic EL element OLED3 is formed of the same material in the same fabrication step, and has substantially equal film thickness.

The second hole transport layer HTL2 is disposed on the second light transmission layer EM2 of the third organic EL element OLED3. Part of the second hole transport layer HTL2 extends onto the partition wall PI which surrounds the third organic EL element OLED3.

The third light emission layer EM3 extends over the first organic EL element OLED1 and the third organic EL element OLED3 which are arranged in the X direction. Specifically, the third light emission layer EM3 is disposed on the first light emission layer EM1 of the first organic EL element OLED1, and on the second hole transport layer HTL2 of the third organic EL element OLED3. In addition, the third light emission layer EM3 is disposed on the first emission layer EM1 above the partition wall PI which is disposed between the first organic EL element OLED1 and the third organic EL element OLED3. The third light emission layer EM3 in each of the first organic EL element OLED1 and third organic EL element OLED3 is formed of the same material in the same fabrication step, and has substantially equal film thickness.

The electron transport layer ETL extends over the first to third organic EL elements OLED1 to OLED3. In addition, the electron transport layer ETL is disposed on the first hole transport layer HTL1 above the partition walls PI which are disposed between the first organic EL element OLED1 and the second organic EL element OLED2. In addition, the electron transport layer ETL is disposed on the second light emission layer EM2 above the partition wall PI which is disposed between the second organic EL element OLED2 and the third organic EL element OLED3. Further, the electron transport layer ETL is disposed on the third light emission layer EM3 above the partition wall PI which is disposed between the third organic EL element OLED3 and the first organic EL element OLED1.

The counter-electrode CE extends over the first to third organic EL elements OLED1 to OLED3, and is disposed on the electron transport layer ETL above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first to third organic EL elements OLED1 to OLED3 are sealed by using the sealing glass substrate SUB2.

In Example 7, the same advantageous effects as in Example 5 and Example 6 can be obtained.

In addition, in Example 7, the minimum opening size of the fine mask which is needed for forming the first to third organic EL elements OLED1 to OLED3 is substantially equal to the size of the light emission section EA3. Specifically, of the layers which constitute the organic layer ORG that is formed by evaporation deposition, the layers other than the second hole transport layer HTL2 extend over two or more organic EL elements. On the other hand, the second hole transport layer HTL2 is formed on the area that is substantially equal to the area of the light emission section EA3. As has been described above, the area of the light emission section EA3 is greater than each of the area of the light emission sections EA1 and EA2. Thus, the minimum opening size of the fine mask, which is used in Example 7, is substantially equal to the area of the light emission section EA3, and the minimum opening size can be made greater, compared to Example 6. Therefore, the structure of Example 7 is advantageous in achieving higher fineness.

Moreover, the organic layer ORG of the third organic EL element OLED3 includes the first light emission layer EM1 and second light emission layer EM2 on the pixel electrode side of the third light emission layer EM3. Since the first light emission layer EM1 and second light emission layer EM2 are disposed between the first hole transport layer HTL1 and second hole transport layer HTL2, the first light emission layer EM1 and second light emission layer EM2 are formed of a material with hole transport properties. Specifically, in Example 7, the first light emission layer EM1 including the first light-emitting material which emits red light, and the second light emission layer EM2 including the second light-emitting material which emits green light function as a third hole transport layer and a fourth hole transport layer, respectively. By selecting the materials with hole transport properties as the materials of which the first light emission layer EM1 and second light emission layer EM2 are formed, the hole transport from the pixel electrode PE to the third light emission layer EM3 is not hindered, and it is possible to prevent an increase in driving voltage and a decrease in light emission efficiency in the third organic EL element OLED3.

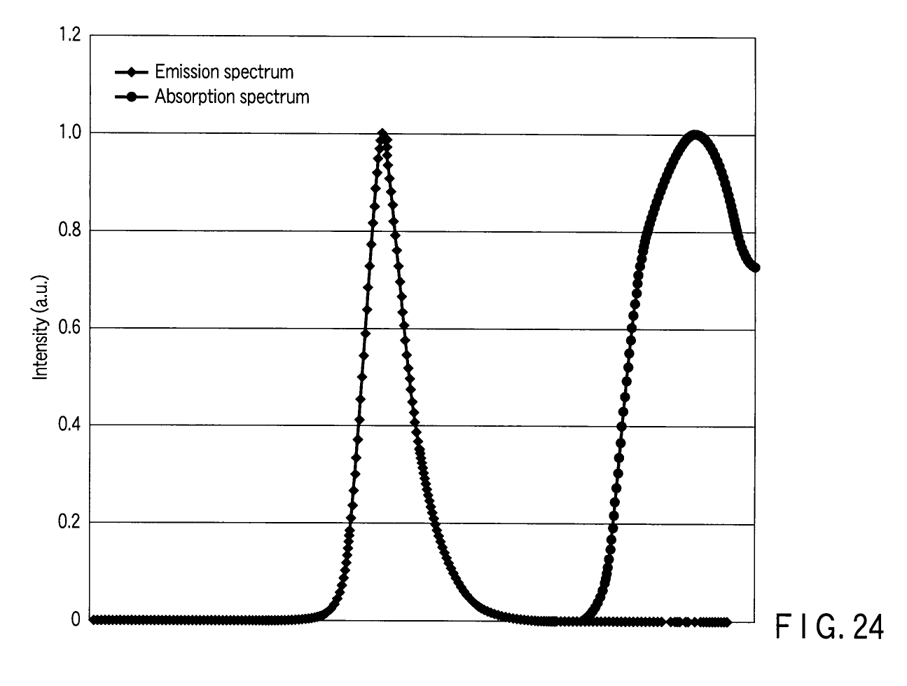

As shown in FIG. 24 as an image, it is desirable that the emission spectrum of the third light emission layer EM3 and the absorption spectrum of each of the first emission light layer EM1 and second light emission layer EM2 do not overlap. By selecting such materials, the absorption of emission light from the third light emission layer EM3 in the first emission light layer EM1 and second light emission layer EM2 can be suppressed in the third organic EL element OLED3, and the decrease in light emission efficiency can be suppressed.

In Example 7, all the device variations that have been described in Example 1 are applicable.

### EXAMPLE 8

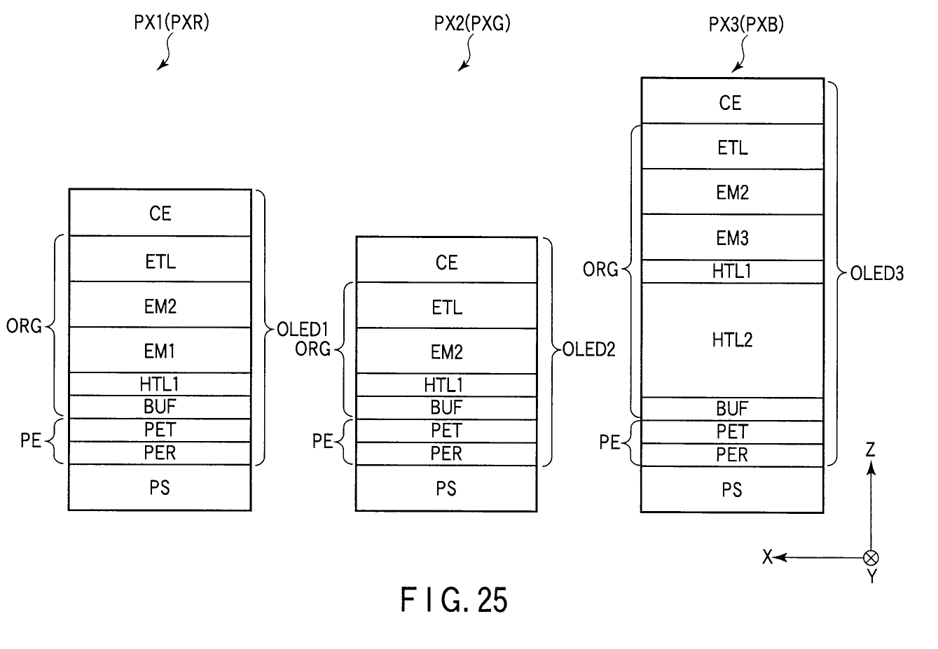

FIG. 25 schematically shows the structures of the first to third organic EL elements OLED1 to OLED3 in Example 8. Example 8 shown in FIG. 25 differs from Example 4 shown in FIG. 13 in that a second light emission layer EM2 is disposed in place of the third light emission layer EM3 between the first light emission layer EM1 and the electron transport layer ETL in the organic layer ORG of the first organic EL element OLED1, and in that a second light emission layer EM2 is disposed between the third light emission layer EM3 and the electron transport layer ETL in the organic layer ORG of the third organic EL element OLED3. In the organic layer ORG of the first organic EL element OLED1, the second light emission layer EM2 emits no light, and functions as a hole blocking layer. In addition, in the organic layer ORG of the third organic EL element OLED3, the second light emission layer EM2 emits no light.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a buffer layer BUF, a first hole transport layer HTL1, a first light emission layer EM1, a second light emission layer EM2 and an electron transport layer ETL are stacked in the named order between a reflective layer PER and a counter-electrode CE. In the second organic EL element OLED2, a transmissive layer PET, a buffer layer BUF, a first hole transport layer HTL1, a second light emission layer EM2 and an electron transport layer ETL are stacked in the named order between a reflective layer PER and a counter-electrode CE. In the third organic EL element OLED3, a transmissive layer PET, a buffer layer BUF, a second hole transport layer HTL2, a first hole transport layer HTL1, a third light emission layer EM3, a second light transmission layer EM2, and an electron transport layer ETL are stacked in the named order between a reflective layer PER and a counter-electrode CE.

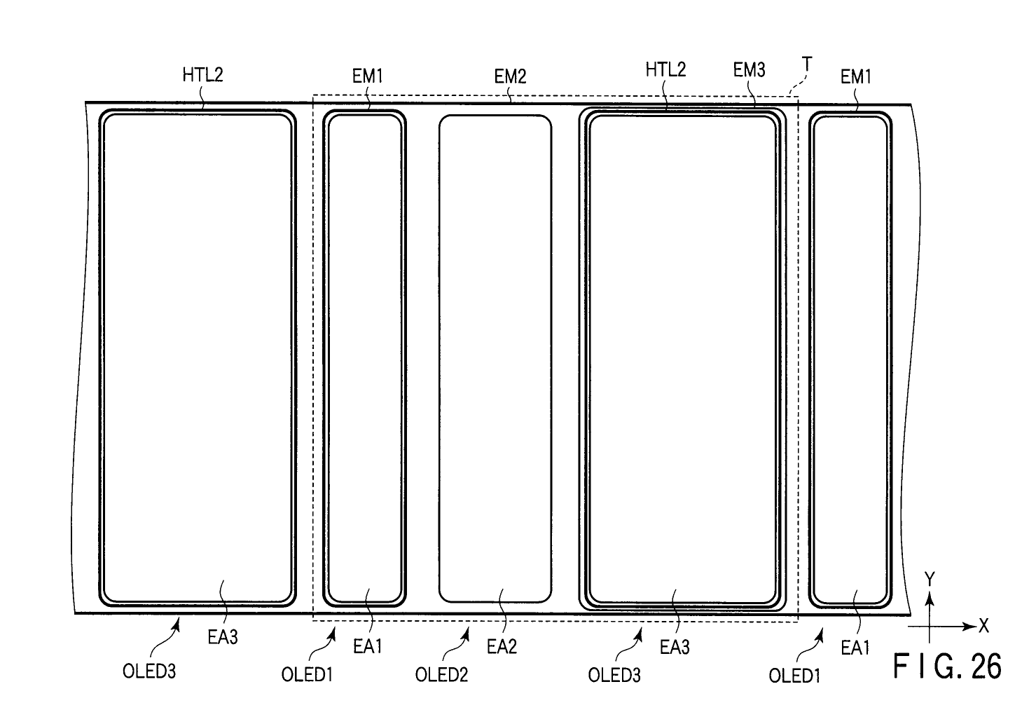

FIG. 26 schematically shows the first light emission layer EM1, second light emission layer EM2, third light emission layer EM3 and second hole transport layer HTL2, which are disposed in the triplet T in Example 8. Example 8 shown in FIG. 26 differs from Example 4 in that the second light emission layer EM2 is disposed over the light emission section EA1 of the first organic EL element OLED1, the light emission section EA2 of the second organic EL element OLED2 and the light emission section EA3 of the third organic EL element OLED3, which neighbor in the X direction.

The first light emission layer EM1 is disposed on an area which is equal to or greater than the area of the light emission section EA1 of the first organic EL element OLED1. The third light emission layer EM3 and the second hole transport layer HTL2 are disposed on an area which is equal to or greater than the area of the light emission section EA3 of the third organic EL element OLED3.

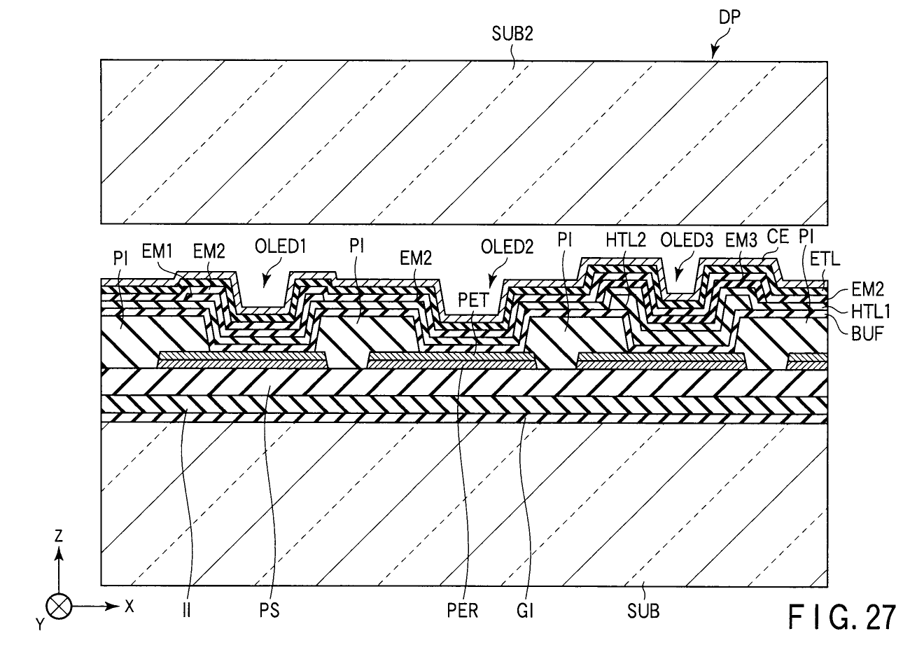

FIG. 27 schematically shows a cross-sectional structure of the display panel DP which includes the first to third organic EL elements OLED1 to OLED3 in Example 8. In FIG. 27, the dimensions in the X direction are different from those in FIG. 26 in order to clarify the structures of the first to third organic EL elements OLED1 to OLED3.

Example 8 shown in FIG. 27 differs from Example 4 shown in FIG. 14 in that the second light emission layer EM2 extends not only over the second organic EL element OLED2, but also over the first organic EL element OLED1 and the third organic EL element OLED3.

The gate insulation film GI, interlayer insulation film II and passivation film PS are disposed between the substrate SUB and each reflective layer PER. The reflective layer PER and transmissive layer PET of each of the first to third organic EL elements OLED1 to OLED3 are disposed on the passivation film PS.

The buffer layer BUF extends over the first to third organic EL elements OLED1 to OLED3, and is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The second hole transport layer HTL2 is disposed on the buffer layer BUF of the third organic EL element OLED3, and part of the second hole transport layer HTL2 extends onto the partition wall PI which surrounds the third organic EL element OLED3.

The first hole transport layer HTL1 extends over the first to third organic EL elements OLED1 to OLED3. Specifically, the first hole transport layer HTL1 is disposed on the buffer layer BUF in the first organic EL element OLED1 and the second organic EL element OLED2. In addition, the first hole transport layer HTL1 is disposed on the second hole transport layer HTL2 in the third organic EL element OLED3. Further, the first hole transport layer HTL1 is disposed on the buffer layer BUF above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed on the first hole transport layer HTL1 of the first organic EL element OLED1, and part of the first light emission layer EM1 extends onto the partition wall PI surrounding the first organic EL element OLED1.

The third light emission layer EM3 is disposed on the first hole transport layer HTL1 of the third organic EL element OLED3, and part of the third light emission layer EM3 extends onto the partition wall PI surrounding the third organic EL element OLED3.

The second light emission layer EM2 is disposed in the second organic EL element OLED2, and extends to the first organic EL element OLED1 and third organic EL element OLED3 which neighbor the second organic EL element OLED2 in the X direction. Specifically, the second light emission layer EM2 is disposed on the first hole transport layer HTL1 of the second organic EL element OLED2. In addition, the second light emission layer EM2 is disposed on the first light emission layer EM1 of the first organic EL element OLED1, and on the third light emission layer EM3 of the third organic EL element OLED3. Further, the second light emission layer EM2 is disposed on the first hole transport layer HTL1 above the partition walls PI which are disposed between the first organic EL element OLED1 and the second organic EL element OLED2, between the second organic EL element OLED2 and the third organic EL element OLED3 and between the third organic EL element OLED3 and the first organic EL element OLED1.

The electron transport layer ETL extends over the first to third organic EL elements OLED1 to OLED3. The electron transport layer ETL is disposed on the second light emission layer EM2 in each of the first to third organic EL elements OLED1 to OLED3. In addition, the electron transport layer ETL is disposed on the second light emission layer EM2 above the partition walls PI which are disposed between the first organic EL element OLED1 and the second organic EL element OLED2, between the second organic EL element OLED2 and the third organic EL element OLED3 and between the third organic EL element OLED3 and the first organic EL element OLED1.

The counter-electrode CE extends over the first to third organic EL elements OLED1 to OLED3, and is disposed on the electron transport layer ETL in each of the first to third organic EL element OLED1 to OLED3. In addition, the counter-electrode CE is disposed on the electron transport layer ETL above the partition walls PI which are disposed between the first organic EL element OLED1 and the second organic EL element OLED2, between the second organic EL element OLED2 and the third organic EL element OLED3 and between the third organic EL element OLED3 and the first organic EL element OLED1.

The first to third organic EL elements OLED1 to OLED3 are sealed by using the sealing glass substrate SUB2.

In Example 8, the same advantageous effects as in Example 4 can be obtained.

In addition, the second light emission layer EM2 is the continuous film spreading over the first organic EL element OLED1 to third organic EL element OLED3. Thus, when the second light emission layer EM2 is formed by evaporation deposition, use is made of a mask in which an opening connecting the light emission sections EA1 to EA3 is formed. In Example 4, a fine mask is needed when the first light emission layer EM1, second light emission layer EM2, third light emission layer EM3 and second hole transport layer HTL2 are formed. In Example 8, a fine mask for forming the second light emission layer EM2 is not necessary, and the manufacturing cost of the mask can be reduced. Furthermore, the amount of material, which is deposited on the mask at the time of forming the second light emission layer EM2, decreases, and the efficiency of use of the material for forming the second light emission layer EM2 can be enhanced.

Moreover, since the second light emission layer EM2, which is disposed in the third organic EL element OLED3, is usable for optical path length adjustment, the film thickness of the second hole transport layer HTL2 can be reduced by a degree corresponding to the film thickness of the second light emission layer EM2. Therefore, the amount of material that is used for forming the second hole transport layer HTL2 can be reduced, and the cost of material can be decreased.

In Example 8, all the device variations that have been described in Example 1 are applicable.

### EXAMPLE 9

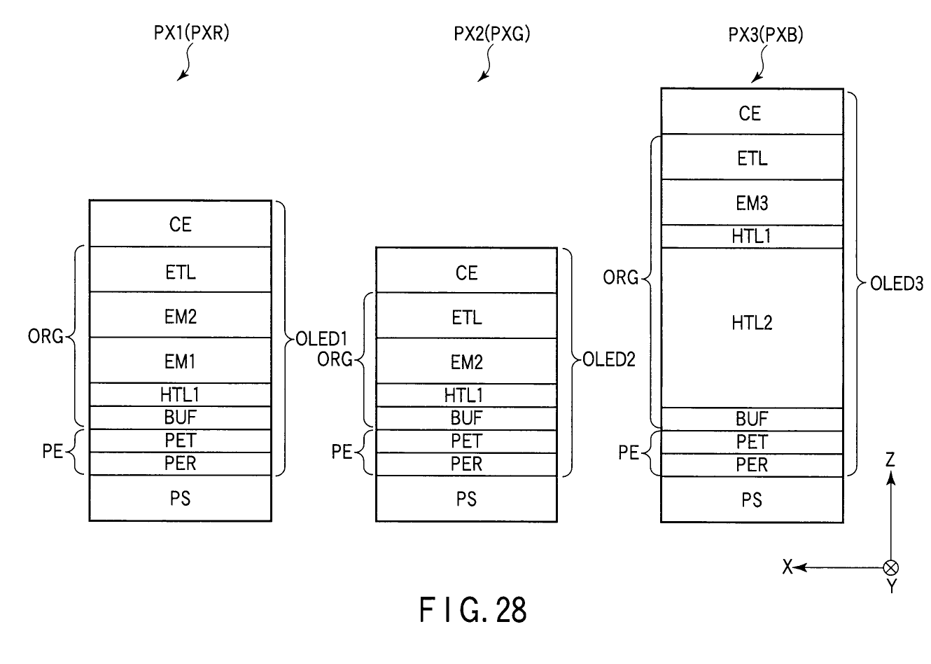

FIG. 28 schematically shows the structures of the first to third organic EL elements OLED1 to OLED3 in Example 9. Example 9 shown in FIG. 28 differs from Example 4 shown in FIG. 13 in that a second light emission layer EM2 is disposed in place of the third light emission layer EM3 between the first light emission layer EM1 and the electron transport layer ETL in the organic layer ORG of the first organic EL element OLED1. In the organic layer ORG of the first organic EL element OLED1, the second light emission layer EM2 emits no light, and functions as a hole blocking layer.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a buffer layer BUF, a first hole transport layer HTL1, a first light emission layer EM1, a second light emission layer EM2 and an electron transport layer ETL are stacked in the named order between a reflective layer PER and a counter-electrode CE. In the second organic EL element OLED2, a transmissive layer PET, a buffer layer BUF, a first hole transport layer HTL1, a second light emission layer EM2 and an electron transport layer ETL are stacked in the named order between a reflective layer PER and a counter-electrode CE. In the third organic EL element OLED3, a transmissive layer PET, a buffer layer BUF, a second hole transport layer HTL2, a first hole transport layer HTL1, a third light emission layer EM3, and an electron transport layer ETL are stacked in the named order between a reflective layer PER and a counter-electrode CE.

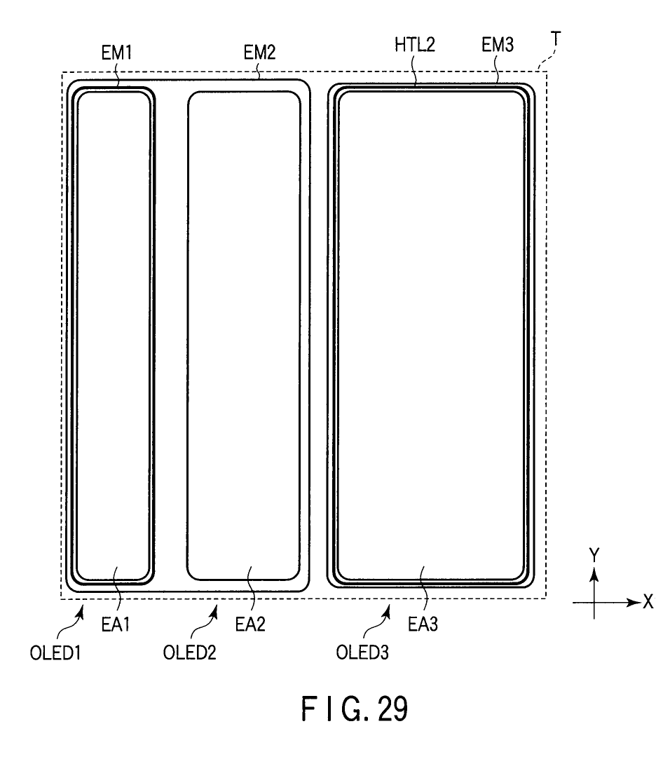

FIG. 29 schematically shows the first light emission layer EM1, second light emission layer EM2, third light emission layer EM3 and second hole transport layer HTL2, which are disposed in the triplet T in Example 9. Example 9 shown in FIG. 29 differs from Example 4 in that the second light emission layer EM2 is disposed over the light emission section EA1 of the first organic EL element OLED1 and the light emission section EA2 of the second organic EL element OLED2, which neighbor in the X direction.

The first light emission layer EM1 is disposed on an area which is equal to or greater than the area of the light emission section EA1 of the first organic EL element OLED1. The third light emission layer EM3 and the second hole transport layer HTL2 are disposed on an area which is equal to or greater than the area of the light emission section EA3 of the third organic EL element OLED3.

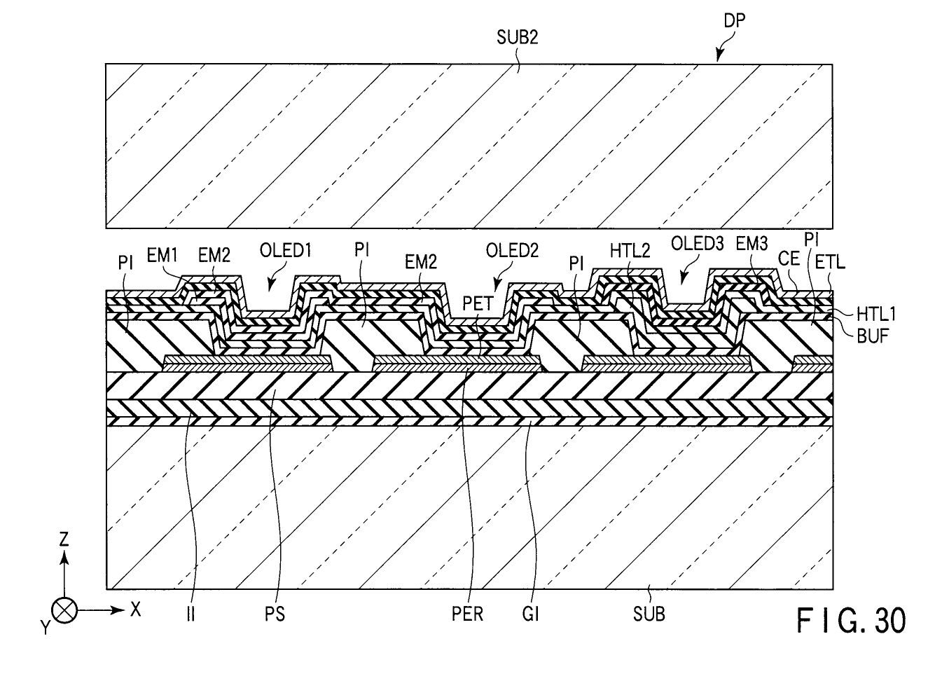

FIG. 30 schematically shows a cross-sectional structure of the display panel DP which includes the first to third organic EL elements OLED1 to OLED3 in Example 9. In FIG. 30, the dimensions in the X direction are different from those in FIG. 29 in order to clarify the structures of the first to third organic EL elements OLED1 to OLED3.

Example 9 shown in FIG. 30 differs from Example 4 shown in FIG. 14 in that the second light emission layer EM2 extends not only over the second organic EL element OLED2, but also over the first organic EL element OLED1.

The gate insulation film GI, interlayer insulation film II and passivation film PS are disposed between the substrate SUB and each reflective layer PER. The reflective layer PER and transmissive layer PET of each of the first to third organic EL elements OLED1 to OLED3 are disposed on the passivation film PS.

The buffer layer BUF extends over the first to third organic EL elements OLED1 to OLED3, and is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The second hole transport layer HTL2 is disposed on the buffer layer BUF of the third organic EL element OLED3, and part of the second hole transport layer HTL2 extends onto the partition wall PI which surrounds the third organic EL element OLED3.

The first hole transport layer HTL1 extends over the first to third organic EL elements OLED1 to OLED3. Specifically, the first hole transport layer HTL1 is disposed on the buffer layer BUF in the first organic EL element OLED1 and the second organic EL element OLED2. In addition, the first hole transport layer HTL1 is disposed on the second hole transport layer HTL2 in the third organic EL element OLED3. Further, the first hole transport layer HTL1 is disposed on the buffer layer BUF above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed on the first hole transport layer HTL1 of the first organic EL element OLED1, and part of the first light emission layer EM1 extends onto the partition wall PI surrounding the first organic EL element OLED1.

The third light emission layer EM3 is disposed on the first hole transport layer HTL1 of the third organic EL element OLED3, and part of the third light emission layer EM3 extends onto the partition wall PI surrounding the third organic EL element OLED3.

The second light emission layer EM2 is disposed in the second organic EL element OLED2, and extends to the first organic EL element OLED1 which neighbors the second organic EL element OLED2 in the X direction. Specifically, the second light emission layer EM2 is disposed on the first hole transport layer HTL1 of the second organic EL element OLED2. In addition, the second light emission layer EM2 is disposed on the first light emission layer EM1 of the first organic EL element OLED1. Further, the second light emission layer EM2 is disposed on the first hole transport layer HTL1 above the partition wall PI which is disposed between the first organic EL element OLED1 and the second organic EL element OLED2.

The electron transport layer ETL extends over the first to third organic EL elements OLED1 to OLED3. Specifically, the electron transport layer ETL is disposed on the second light emission layer EM2 in each of the first organic EL element OLED1 and the second organic EL element OLED3. In addition, the electron transport layer ETL is disposed on the second light emission layer EM2 above the partition wall PI which is disposed between the first organic EL element OLED1 and the second organic EL element OLED2. Besides, the electron transport layer ETL is disposed on the third light emission layer EM3 in the third organic EL element OLED3. Further, the electron transport layer ETL is disposed on the first hole transport layer HTL1 above the partition walls PI which are disposed between the second organic EL element OLED2 and the third organic EL element OLED3 and between the third organic EL element OLED3 and the first organic EL element OLED1.

The counter-electrode CE extends over the first to third organic EL elements OLED1 to OLED3, and is disposed on the electron transport layer ETL in each of the first to third organic EL element OLED1 to OLED3. In addition, the counter-electrode CE is disposed on the electron transport layer ETL above the partition walls PI which are disposed between the first organic EL element OLED1 and the second organic EL element OLED2, between the second organic EL element OLED2 and the third organic EL element OLED3 and between the third organic EL element OLED3 and the first organic EL element OLED1.

The first to third organic EL elements OLED1 to OLED3 are sealed by using the sealing glass substrate SUB2.

In Example 9, the same advantageous effects as in Example 4 can be obtained.

In addition, the second light emission layer EM2 is the continuous film spreading over the first organic EL element OLED1 and second organic EL element OLED2. Thus, when the second light emission layer EM2 is formed by evaporation deposition, use is made of a mask in which an opening connecting the light emission sections EA1 and EA2 is formed. In other words, the opening size of the mask can be increased, and the manufacturing cost of the mask can be reduced. Furthermore, the amount of material, which is deposited on the mask at the time of forming the second light emission layer EM2, decreases, and the efficiency of use of the material for forming the second light emission layer EM2 can be enhanced.

In Example 9, all the device variations that have been described in Example 1 are applicable.

### EXAMPLE 10

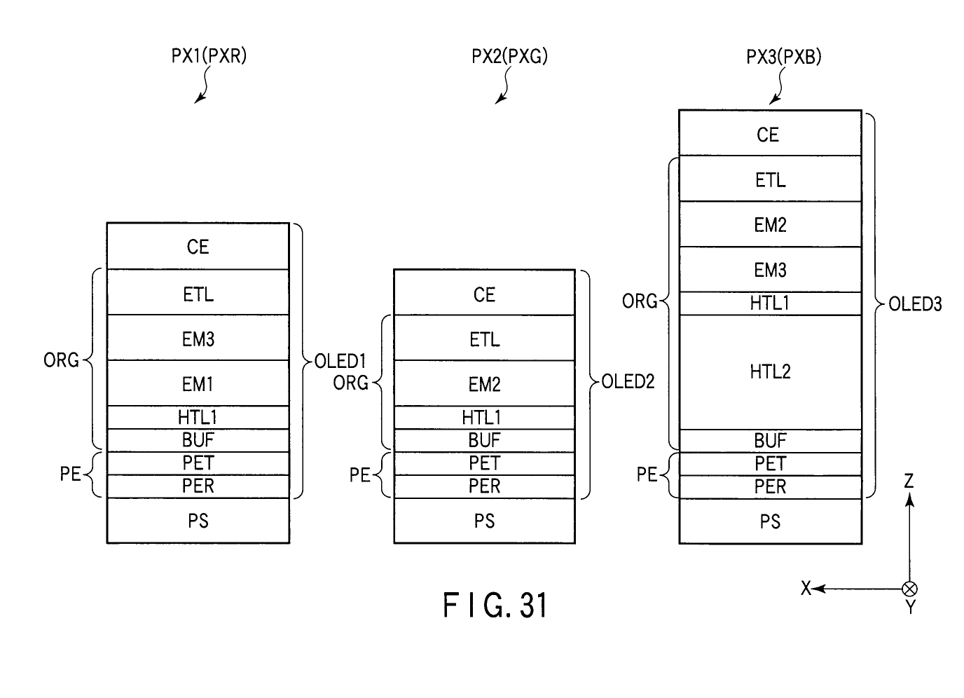

FIG. 31 schematically shows the structures of the first to third organic EL elements OLED1 to OLED3 in Example 10. Example 10 shown in FIG. 31 differs from Example 4 shown in FIG. 13 in that a second light emission layer EM2 is provided between the third light emission layer EM3 and the electron transport layer ETL in the organic layer ORG of the third organic EL element OLED3. In the organic layer ORG of the first organic EL element OLED1, the third light emission layer EM3 emits no light, and functions as a hole blocking layer. In addition, in the organic layer ORG of the third organic EL element OLED3, the second light emission layer EM2 emits no light.

The first organic EL element OLED1 of the pixel PX1, the second organic EL element OLED2 of the pixel PX2 and the third organic EL element OLED3 of the pixel PX3 are disposed on the passivation film PS.

In the first organic EL element OLED1, a transmissive layer PET, a buffer layer BUF, a first hole transport layer HTL1, a first light emission layer EM1, a third light emission layer EM3 and an electron transport layer ETL are stacked in the named order between a reflective layer PER and a counter-electrode CE. In the second organic EL element OLED2, a transmissive layer PET, a buffer layer BUF, a first hole transport layer HTL1, a second light emission layer EM2 and an electron transport layer ETL are stacked in the named order between a reflective layer PER and a counter-electrode CE. In the third organic EL element OLED3, a transmissive layer PET, a buffer layer BUF, a second hole transport layer HTL2, a first hole transport layer HTL1, a third light emission layer EM3, a second light emission layer EM2, and an electron transport layer ETL are stacked in the named order between a reflective layer PER and a counter-electrode CE.

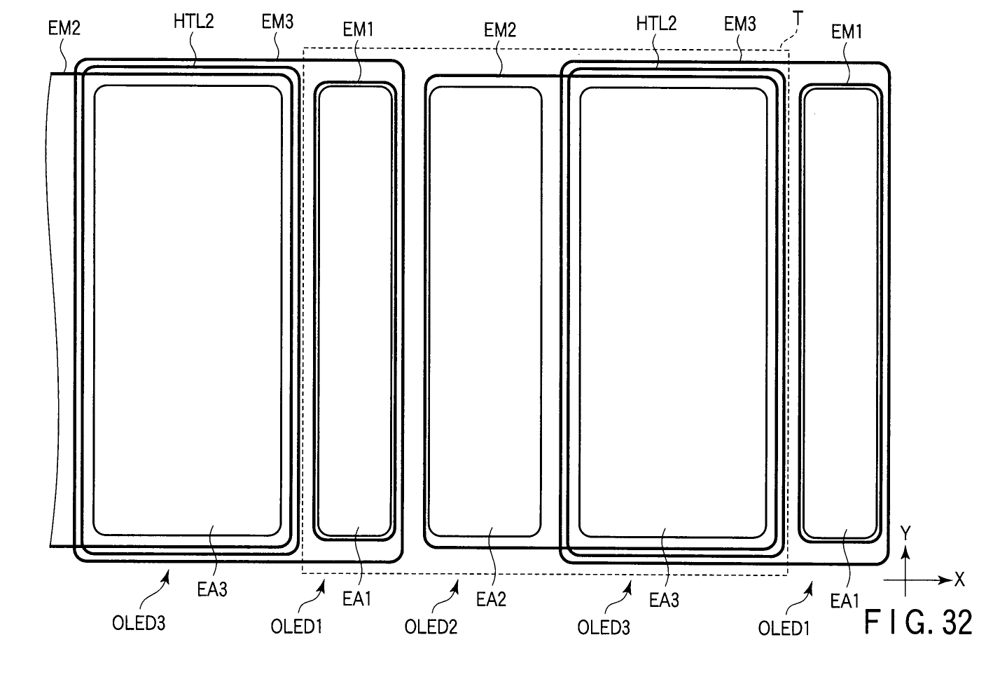

FIG. 32 schematically shows the first light emission layer EM1, second light emission layer EM2, third light emission layer EM3 and second hole transport layer HTL2, which are disposed in the triplet T in Example 10. Example 10 shown in FIG. 32 differs from Example 4 in that the second light emission layer EM2 is disposed over the light emission section EA2 of the second organic EL element OLED2 and the light emission section EA3 of the third organic EL element OLED3, which neighbor in the X direction.

The first light emission layer EM1 is disposed on an area which is equal to or greater than the area of the light emission section EA1 of the first organic EL element OLED1. The third light emission layer EM3 is disposed over the light emission section EA3 of the third organic EL element OLED3 and the light emission section EA1 of the first organic EL element OLED1, which neighbor in the X direction. The second hole transport layer HTL2 is disposed on an area which is equal to or greater than the area of the light emission section EA3 of the third organic EL element OLED3.

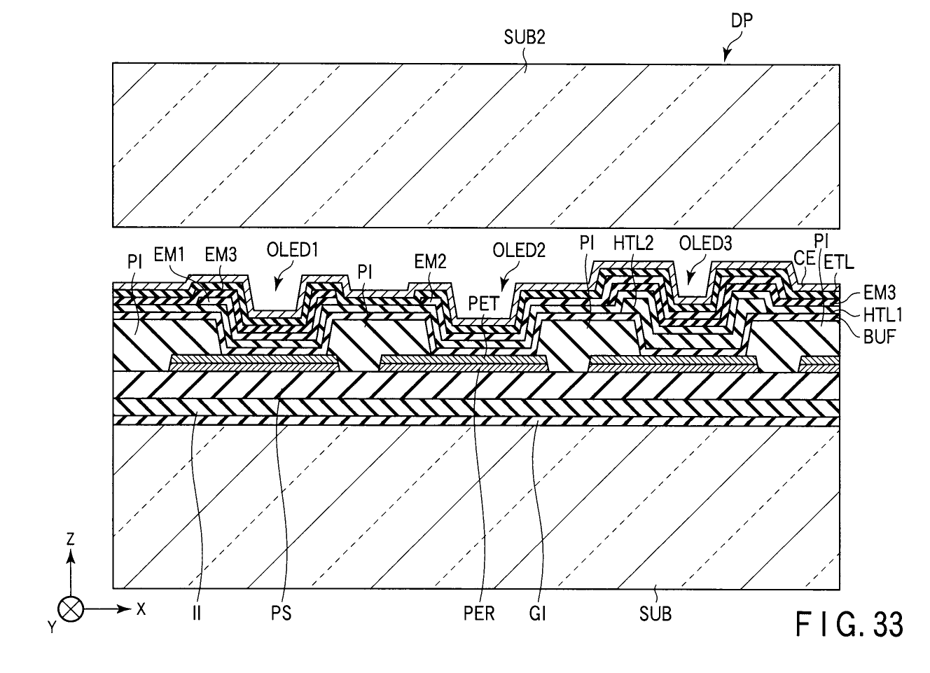

FIG. 33 schematically shows a cross-sectional structure of the display panel DP which includes the first to third organic EL elements OLED1 to OLED3 in Example 10. In FIG. 33, the dimensions in the X direction are different from those in FIG. 32 in order to clarify the structures of the first to third organic EL elements OLED1 to OLED3.

Example 10 shown in FIG. 33 differs from Example 4 shown in FIG. 14 in that the second light emission layer EM2 extends not only over the second organic EL element OLED2, but also over the third organic EL element OLED3.

The gate insulation film GI, interlayer insulation film II and passivation film PS are disposed between the substrate SUB and each reflective layer PER. The reflective layer PER and transmissive layer PET of each of the first to third organic EL elements OLED1 to OLED3 are disposed on the passivation film PS.

The buffer layer BUF extends over the first to third organic EL elements OLED1 to OLED3, and is disposed on the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The second hole transport layer HTL2 is disposed on the buffer layer BUF of the third organic EL element OLED3. Part of the second hole transport layer HTL2 extends onto the partition wall PI which surrounds the third organic EL element OLED3.

The first hole transport layer HTL1 extends over the first to third organic EL elements OLED1 to OLED3. Specifically, the first hole transport layer HTL1 is disposed on the buffer layer BUF in each of the first organic EL element OLED1 and second organic EL element OLED2. In addition, the first hole transport layer HTL1 is disposed on the second hole transport layer HTL2 in the third organic EL element OLED3. Further, the first hole transport layer HTL1 is disposed on the buffer layer BUF above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first light emission layer EM1 is disposed on the first hole transport layer HTL1 of the first organic EL element OLED1. Part of the first light emission layer EM1 extends onto the partition wall PI surrounding the first organic EL element OLED1.

The third light emission layer EM3 is disposed in the third organic EL element OLED3, and extends to the first organic EL element OLED1 which neighbors the third organic EL element OLED3 in the X direction. Specifically, the third light emission layer EM3 is disposed on the first light emission layer EM1 of the first organic EL element OLED1, and on the first hole transport layer HTL1 of the third organic EL element OLED3. In addition, the third light emission layer EM3 is disposed on the first hole transport layer HTL1 above the partition wall PI which is disposed between the first organic EL element OLED1 and the third organic EL element OLED3.

The second light emission layer EM2 is disposed in the second organic EL element OLED2, and extends to the third organic EL element OLED3 which neighbors the second organic EL element OLED2 in the X direction. Specifically, the second light emission layer EM2 is disposed on the first hole transport layer HTL1 of the second organic EL element OLED2. In addition, the second light emission layer EM2 is disposed on the third light emission layer EM3 of the third organic EL element OLED3. Further, the second light emission layer EM2 is disposed on the first hole transport layer HTL1 above the partition wall PI which is disposed between the second organic EL element OLED2 and the third organic EL element OLED3.

The electron transport layer ETL extends over the first to third organic EL elements OLED1 to OLED3. Specifically, the electron transport layer ETL is disposed on the second light emission layer EM2 in each of the second organic EL element OLED2 and the third organic EL element OLED3. In addition, the electron transport layer ETL is disposed on the second light emission layer EM2 above the partition wall PT which is disposed between the second organic EL element OLED2 and the third organic EL element OLED3. Further, the electron transport layer ETL is disposed on the third light emission layer EM3 in the first organic EL element OLED1. The electron transport layer ETL is also disposed on the first hole transport layer HTL1 above the partition wall PI which is disposed between the first organic EL element OLED1 and the second organic EL element OLED2. Besides, the electron transport layer ETL is disposed on the third light emission layer EM3 above the partition wall PI which is disposed between the third organic EL element OLED3 and the first organic EL element OLED1.

The counter-electrode CE extends over the first to third organic EL elements OLED1 to OLED3, and is disposed on the electron transport layer ETL in each of the first to third organic EL elements OLED1 to OLED3. In addition, the counter-electrode CE is disposed on the electron transport layer ETL above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first to third organic EL elements OLED1 to OLED3 are sealed by using the sealing glass substrate SUB2.

In Example 10, the same advantageous effects as in Example 4 can be obtained.

In addition, the second light emission layer EM2 is the continuous film spreading over the second organic EL element OLED2 and third organic EL element OLED3. Thus, when the second light emission layer EM2 is formed by evaporation deposition, use is made of a mask in which an opening connecting the light emission sections EA2 and EA3 is formed. Specifically, the size of the opening in the mask can be increased, and the manufacturing cost of the mask can be reduced. Furthermore, the amount of material, which is deposited on the mask at the time of forming the second light emission layer EM2, decreases, and the efficiency of use of the material for forming the second light emission layer EM2 can be enhanced.

Besides, the third light emission layer EM3 is the continuous film spreading over the first organic EL element OLED1 and third organic EL element OLED3. Thus, when the third light emission layer EM3 is formed by evaporation deposition, use is made of a mask in which an opening connecting the light emission sections EA1 and EA3 is formed. Specifically, the size of the opening in the mask can be increased, and the manufacturing cost of the mask can be reduced. Moreover, the amount of material, which is deposited on the mask at the time of forming the third light emission layer EM3, decreases, and the efficiency of use of the material for forming the third light emission layer EM3 can be enhanced.

Furthermore, since the second light emission layer EM2, which is disposed in the third organic EL element OLED3, is usable for optical path length adjustment, the film thickness of the second hole transport layer HTL2 can be reduced by a degree corresponding to the film thickness of the second light emission layer EM2. Therefore, the amount of material that is used for forming the second hole transport layer HTL2 can be reduced, and the cost of material can be decreased.

In Example 10, all the device variations that have been described in Example 1 are applicable.

The present invention is not limited directly to the above-described embodiments. In practice, the structural elements can be modified and embodied without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

In the above-described embodiments, the organic EL display device includes three kinds of organic EL elements with different emission light colors, namely, the first to third organic EL elements OLED1 to OLED3. Alternatively, the organic EL display device may include, as organic EL elements, only two kinds of organic EL elements with different emission light colors, or four or more kinds of organic EL elements with different emission light colors.

In the above-described embodiments, all of the first to third light-emitting materials may be fluorescent materials or phosphorescent materials. Alternatively, one or two of the first to third light-emitting materials may be a fluorescent material or fluorescent materials, and the other two or one may be phosphorescent materials or a phosphorescent material.

Each of the above-described embodiments may include an electron injection layer, or a hole injection layer, or both the electron injection layer and hole injection layer.

In the above-described Examples 1 to 4 and Examples 8 to 10, the first hole transport layer HTL1 is disposed on the second hole transport layer HTL2 in the third organic EL element OLED3. Alternatively, the second hole transport layer HTL2 may be disposed on the first hole transport layer HTL1.

In the above-described Examples 5 to 7, the second hole transport layer HTL2 is disposed on the first hole transport layer HTL1 in the third organic EL element OLED3. Alternatively, the first hole transport layer HTL1 may be disposed on the second hole transport layer HTL2.

What is claimed is:

1. An organic EL display device comprising:
a first organic EL element which includes a first anode, a cathode, and a first organic layer including a first light emission layer which emits the color of light in the first wavelength range and a hole blocking layer between the first anode and the cathode;
a second organic EL element which includes a second anode, the cathode extending from the first organic EL element, and a second organic layer including a second light emission layer which emits the color of light in the first wavelength range between the second anode and the cathode, the second organic EL element being thinner than the first organic EL element; and
a third organic EL element which includes a third anode, the cathode extending from the second organic EL element, and a third organic layer including a third light emission layer which emits the color of light in the first wavelength range between the third anode and the cathode, the third organic EL element being thicker than the first organic EL element.

2. The organic EL display device according to claim 1, wherein the first anode includes a first reflective layer, the second anode includes a second reflective layer, the third anode includes a third reflective layer, and the cathode includes a semi-transmissive layer.

3. The organic EL display device according to claim 1, wherein the hole blocking layer is the second light emission layer extending from the second organic EL element, or the third light emission layer extending from the third organic EL element.

4. The organic EL display device according to claim 3, further comprising a partition wall which is disposed between the first organic EL element and the second organic EL element, wherein the second light emission layer extends above the partition wall.

5. The organic EL display device according to claim 3, further comprising a partition wall which is disposed between the first organic EL element and the third organic EL element, wherein the third light emission layer extends above the partition wall.

6. The organic EL display device according to claim 1, wherein the first organic layer of the first organic EL element includes a first hole transport layer which is disposed between the first anode and the first light emission layer, and an electron transport layer which is disposed between the hole blocking layer and the cathode,
the second organic layer of the second organic EL element includes the first hole transport layer which is disposed between the second anode and the second light emission layer and extends from the first organic EL element, and the electron transport layer which is disposed between the second light emission layer and the cathode and extends from the first organic EL element, and
the third organic layer of the third organic EL element includes the first hole transport layer which is disposed between the third anode and the third light emission layer and extends from the first organic EL element and the second organic EL element, the electron transport layer which is disposed between the third light emission layer and the cathode and extends from the first organic EL element and the second organic EL element, and a second hole transport layer which is disposed between the third anode and the third light emission layer.

7. The organic EL display device according to claim 6, wherein the hole blocking layer is the third light emission layer extending from the third organic EL element, and
the second organic layer of the second organic EL element includes the third light emission layer which is disposed between the second light emission layer and the electron transport layer and extends from the first organic EL element and the third organic EL element.

8. The organic EL display device according to claim 6, wherein the first organic layer of the first organic EL element includes a buffer layer which is disposed between the first anode and the first hole transport layer,
the second organic layer of the second organic EL element includes the buffer layer which is disposed between the second anode and the first hole transport layer and extends from the first organic EL element, and
the third organic layer of the third organic EL element includes the buffer layer which is disposed between the third anode and the second hole transport layer and extends from the first organic EL element and the second organic EL element.

9. The organic EL display device according to claim 6, wherein the third organic layer of the third organic EL element includes the second light emission layer which is disposed between the first hole transport layer and the second hole transport layer and extends from the second organic EL element.

10. The organic EL display device according to claim 9, further comprising a partition wall which is disposed between the second organic EL element and the third organic EL element, wherein the second light emission layer extends above the partition wall.

11. The organic EL display device according to claim 6, wherein the third organic layer of the third organic EL element includes the first light emission layer which is disposed between the first hole transport layer and the second hole transport layer and extends from the first organic EL element.

12. The organic EL display device according to claim 11, further comprising a partition wall which is disposed between the first organic EL element and the third organic EL element, wherein the first light emission layer extends above the partition wall.

13. The organic EL display device according to claim 6, wherein the third organic layer of the third organic EL element includes the first light emission layer which extends from the first organic EL element, and the second light emission layer which extends from the second organic EL element.

14. The organic EL display device according to claim 13, wherein the second light emission layer extends above a partition wall which is disposed between the second organic EL element and the third organic EL element, and the first light emission layer extends above a partition wall which is disposed between the first organic EL element and the third organic EL element.

15. An organic EL display device comprising an organic EL element including:
an anode including a reflective layer;
a first hole transport layer which is disposed above the anode;
a second hole transport layer which is disposed above the first hole transport layer;
a third hole transport layer which is disposed between the first hole transport layer and the second hole transport layer and includes a light-emitting material which emits red light or green light;
a light emission layer which is disposed above the second hole transport layer and includes a light-emitting material which emits blue light;
an electron transport layer which is disposed above the light emission layer; and
a cathode including a semi-transmissive layer which is disposed above the electron transport layer.

16. An organic EL display device comprising an organic EL element including:
an anode including a reflective layer;
a first hole transport layer which is disposed above the anode;
a second hole transport layer which is disposed above the first hole transport layer;
a third hole transport layer including a light-emitting material which emits red light and a fourth hole transport layer including a light-emitting material which emits green light, the third hole transport layer and the fourth hole transport layer being disposed between the first hole transport layer and the second hole transport layer;
a light emission layer which is disposed above the second hole transport layer and includes a light-emitting material which emits blue light;
an electron transport layer which is disposed above the light emission layer; and
a cathode including a semi-transmissive layer which is disposed above the electron transport layer.

17. The organic EL display device according to claim 6, wherein the hole blocking layer is the second light emission layer which extends from the second organic EL element.

18. The organic EL display device according to claim 6, wherein the hole blocking layer is the second light emission layer which extends from the second organic EL element, and
the third organic layer of the third organic EL element includes the second light emission layer which is disposed between the third light emission layer and the electron transport layer and extends from the first organic EL element and the second organic EL element.

19. The organic EL display device according to claim 6, wherein the hole blocking layer is the third light emission layer which extends from the third organic EL element, and
the third organic layer of the third organic EL element includes the second light emission layer which is disposed between the third light emission layer and the electron transport layer and extends from the second organic EL element.

20. The organic EL display device according to claim 1, wherein at least one of the first light emission layer, the second light emission layer and the third light emission layer includes a light-emitting material which is formed of a phosphorescent material.
